(19) United States
(12) Patent Application Publication
(10) Pub. No.: US 2025/0194186 A1
(43) Pub. Date: Jun. 12, 2025

(54) SEMICONDUCTOR DEVICE AND METHOD OF FABRICATING THE SAME

(71) Applicant: Samsung Electronics Co., Ltd., Suwon-si (KR)

(72) Inventors: Yang XU, Suwon-si (KR); Sangmoon LEE, Suwon-si (KR); Gyeom KIM, Suwon-si (KR); Pankwi PARK, Suwon-si (KR); Ryong HA, Suwon-si (KR)

(73) Assignee: Samsung Electronics Co., Ltd., Suwon-si (KR)

(21) Appl. No.: 18/778,162

(22) Filed: Jul. 19, 2024

(30) Foreign Application Priority Data
Dec. 6, 2023 (KR) 10-2023-0175512

(51) Int. Cl. H01L 29/08; H01L 21/8238; H01L 27/092; H01L 29/06; H01L 29/423; H01L 29/66; H01L 29/775; H01L 29/786

(52) U.S. Cl. CPC H10D 62/151; H10D 30/014; H10D 30/43; H10D 30/6735; H10D 30/6757; H10D 62/121; H10D 64/021; H10D 84/017; H10D 84/038; H10D 84/85

(57) ABSTRACT

A semiconductor device including an active pattern on a substrate, a source/drain pattern on the active pattern; a channel pattern on the active pattern and connected to the source/drain pattern and including a first semiconductor pattern, and a gate electrode running across the channel pattern and extending in a first direction may be provided. A first width is a maximum width in the first direction of the source/drain pattern. A second width is a maximum width in the first direction of the first semiconductor pattern. A ratio of the second width to the first width may be in a range of about 0.9 to about 1.1.

### CROSS-REFERENCE TO RELATED APPLICATION

This U.S. nonprovisional application claims priority under 35 U.S.C § 119 to Korean Patent Application No. 10-2023-0175512 filed on Dec. 6, 2023 in the Korean Intellectual Property Office, the disclosure of which is hereby incorporated by reference in its entirety.

### BACKGROUND

The inventive concepts relate to semiconductor devices and methods of fabricating the same, and more particularly, to semiconductor devices including a field effect transistor and methods of fabricating the same.

A semiconductor device includes an integrated circuit including metal oxide semiconductor field effect transistors (MOSFETs). As sizes and design rules of the semiconductor device are gradually decreased, sizes of the MOSFETs are also increasingly scaled down. The scale down of MOSFETs may deteriorate operating characteristics of the semiconductor device. Accordingly, various studies have been conducted to develop methods of fabricating semiconductor devices having superior performances while overcoming limitations caused by high integration of the semiconductor devices.

### SUMMARY

Some example embodiments of the inventive concepts provide semiconductor devices with increased reliability and improved electrical properties.

Some example embodiments of the inventive concepts provide methods of fabricating a semiconductor device with increased reliability and improved electrical properties.

According to an example embodiment of the inventive concepts, a semiconductor device may include an active pattern on a substrate, a source/drain pattern on the active pattern, a channel pattern on the active pattern and connected to the source/drain pattern, the channel pattern including a first semiconductor pattern, and a gate electrode running across the channel pattern and extending in a first direction. A first width may be a maximum width in the first direction of the source/drain pattern. A second width may be a maximum width in the first direction of the first semiconductor pattern. A ratio of the second width to the first width may be in a range of about 0.9 to about 1.1.

According to an example embodiment of the inventive concepts, a semiconductor device may include an active pattern on a substrate, a source/drain pattern on the active pattern, a gate electrode on the active layer and extending in a first direction on the active pattern, and a gate spacer on a sidewall of the source/drain pattern. The source/drain pattern may have a first width in the first direction. The first width may have a maximum value at a bottom surface of the source/drain pattern. The first width may decrease with increasing distance in a vertical direction from the bottom surface.

According to an example embodiment of the inventive concepts, a semiconductor device may include an active pattern on a substrate, a source/drain pattern on the active pattern, a channel pattern on the active pattern and connected to the source/drain pattern, the channel pattern including a plurality of semiconductor patterns that are stacked and spaced apart from each other, a gate electrode running across the channel pattern and extending in a first direction, a gate dielectric layer between the channel pattern and the gate electrode, a gate spacer on a sidewall of the gate electrode, a gate capping pattern on a top surface of the gate electrode, a first interlayer dielectric layer on the gate capping pattern, an active contact penetrating the first interlayer dielectric layer and coupled to the source/drain pattern, a gate contact penetrating the first interlayer dielectric layer and coupled to the gate electrode, a second interlayer dielectric layer on the first interlayer dielectric layer, and a first metal layer in the second interlayer dielectric layer. The first metal layer may include a plurality of first wiring lines electrically connected to the active contact and the gate contact. The gate electrode may include a first gate electrode and a second gate electrode that are adjacent to each other in a second direction orthogonal to the first direction. The gate spacer may include a first part that covers a first sidewall of the first gate electrode, a second part that covers a second sidewall of the second gate electrode, the first sidewall and the second sidewall being opposite to each other in the second direction, and a third part extending along the second direction from the first part to the second part. The source/drain pattern may be in direct contact with the third part.

### BRIEF DESCRIPTION OF DRAWINGS

FIGS. 1 to 3 illustrate conceptual diagrams showing logic cells of a semiconductor device according to some example embodiments of the inventive concepts.

FIG. 4 illustrates a plan view showing a semiconductor device according to an example embodiment of the inventive concepts.

FIGS. 5A, 5B, 5C, and 5D illustrate cross-sectional views taken along lines A-A′, B-B′, C-C′, and D-D′ of FIG. 4, respectively.

FIG. 6A illustrate a top view taken along line M-M′ of FIG. 5A.

FIG. 6B illustrates an enlarged view showing an example embodiment of section L depicted in FIG. 5C.

FIGS. 7A to 15D illustrate cross-sectional views showing a method of fabricating a semiconductor device according to an example embodiment of the inventive concepts.

FIGS. 16 to 18 illustrate enlarged views of section L depicted in FIG. 5C, showing a method of forming a first source/drain pattern, according to an example embodiment of the inventive concepts.

FIGS. 19A, 19B, 19C, and 19D illustrate cross-sectional views taken along lines A-A′, B-B′, C-C′, and D-D′ of FIG. 4, respectively, showing a semiconductor device according to an example embodiment of the inventive concepts.

### DETAILED DESCRIPTION

Some example embodiments of the inventive concepts will now be described in detail with reference to the accompanying drawings to aid in clearly explaining the inventive concepts.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., +10%).

When the terms “about” or “substantially” are used in this specification in connection with a numerical value, it is intended that the associated numerical value includes a manufacturing or operational tolerance (e.g., +10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., +10%) around the stated numerical values or shapes.

As used herein, expressions such as “at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

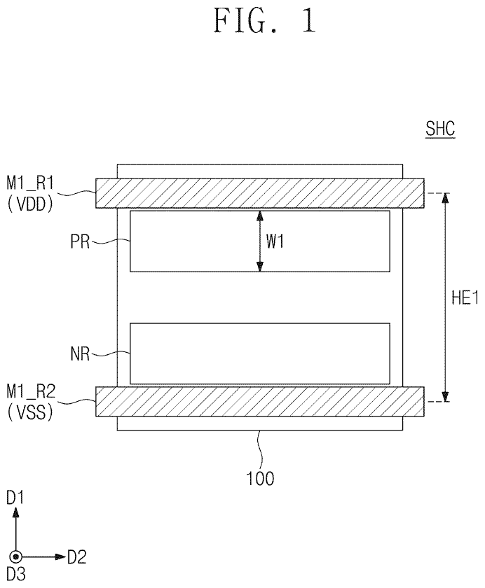

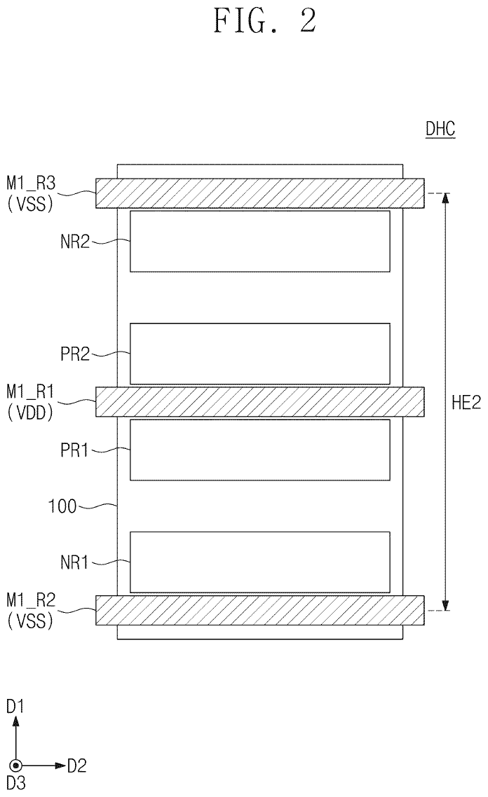

FIGS. 1, 2, and 3 illustrate conceptual views showing logic cells of a semiconductor device according to some example embodiments of the inventive concepts.

Referring to FIG. 1, a single height cell SHC may be provided. For example, a first power line M1_R1 and a second power line M1_R2 may be provided on a substrate 100. The first power line M1_R1 may be a path for providing a drain voltage VDD, for example, a power voltage. The second power line M1_R2 may be a path for providing a source voltage VSS, for example, a ground voltage.

The single height cell SHC may be defined between the first power line M1_R1 and the second power line M1_R2. The single height cell SHC may include one PMOSFET region PR and one NMOSFET region NR. For example, the single height cell SHC may have a complementary metal oxide semiconductor (CMOS) structure provided between the first power line M1_R1 and the second power line M1_R2.

Each of the PMOSFET and NMOSFET regions PR and NR may have a first width W1 in a first direction D1. A first height HE1 may be defined as a length in the first direction D1 of the single height cell SHC. The first height HE1 may be substantially the same as a distance (e.g., pitch) between the first power line M1_R1 and the second power line M1_R2. The single height cell SHC may constitute one logic cell. In this description, the logic cell may mean a logic device (e.g., AND, OR, XOR, XNOR, inverter) that performs a specific function. For example, the logic cell may include transistors for constituting a logic device, and may also include wiring lines that connect the transistors to each other.

Referring to FIG. 2, a double height cell DHC may be provided. For example, a substrate 100 may be provided thereon with a first power line M1_R1, a second power line M1_R2, and a third power line M1_R3. The first power line M1_R1 may be disposed between the second power line M1_R2 and the third power line M1_R3. The third power line M1_R3 may be a path for providing a source voltage VSS.

The double height cell DHC may be defined between the second power line M1_R2 and the third power line M1_R3. The double height cell DHC may include a first PMOSFET region PR1, a second PMOSFET region PR2, a first NMOSFET region NR1, and a second NMOSFET region NR2.

The first NMOSFET region NR1 may be adjacent to the second power line M1_R2. The second NMOSFET region NR2 may be adjacent to the third power line M1_R3. The first and second PMOSFET regions PR1 and PR2 may be adjacent to the first power line M1_R1. When viewed in a plan view, the first power line M1_R1 may be disposed between the first and second PMOSFET regions PR1 and PR2.

A second height HE2 may be defined to indicate a length in the first direction D1 of the double height cell DHC. The second height HE2 may be about twice the first height HE1 of FIG. 1. The first and second PMOSFET regions PR1 and PR2 of the double height cell DHC may collectively operate as a single PMOSFET region.

Therefore, the double height cell DHC may have a PMOS transistor whose channel size is greater than that of a PMOS transistor included in the single height cell SHC discussed above in FIG. 1. For example, the channel size of the PMOS transistor included in the double height cell DHC may be about twice that of the PMOS transistor included in the single height cell SHC. Thus, the double height cell DHC may operate at a higher speed than that of the single height cell SHC. The double height cell DHC shown in FIG. 2 may be referred to as a multi-height cell. Although not shown, the multi-height cell may include a triple height cell whose cell height is about three times that of the single height cell SHC.

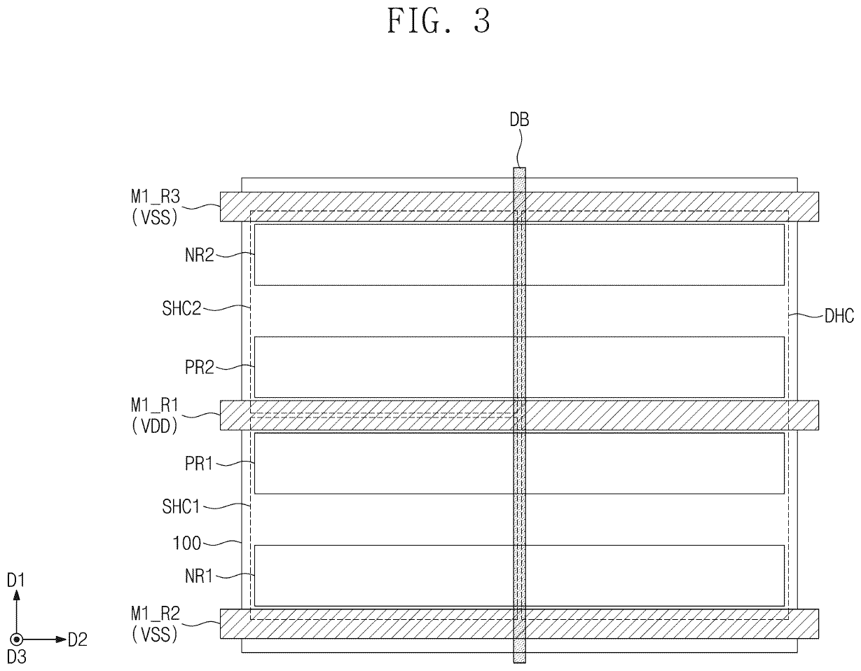

Referring to FIG. 3, a substrate 100 may be provided thereon with a first single height cell SHC1, a second single height cell SHC2, and a double height cell DHC that are two-dimensionally disposed. The first single height cell SHC1 may be disposed between a first power line M1_R1 and a second power line M1_R2. The second single height cell SHC2 may be disposed between the first power line M1_R1 and a third power line M1_R3. The second single height cell SHC2 may be adjacent in a first direction D1 to the first single height cell SHC1.

The double height cell DHC may be disposed between the second power line M1_R2 and the third power line M1_R3. The double height cell DHC may be adjacent in a second direction D2 to the first and second single height cells SHC1 and SHC2.

A separation structure DB may be provided between the first single height cell SHC1 and the double height cell DHC and between the second single height cell SHC2 and the double height cell DHC. The separation structure DB may electrically separate an active region of the double height cell DHC from an active region of each of the first and second single height cells SHC1 and SHC2.

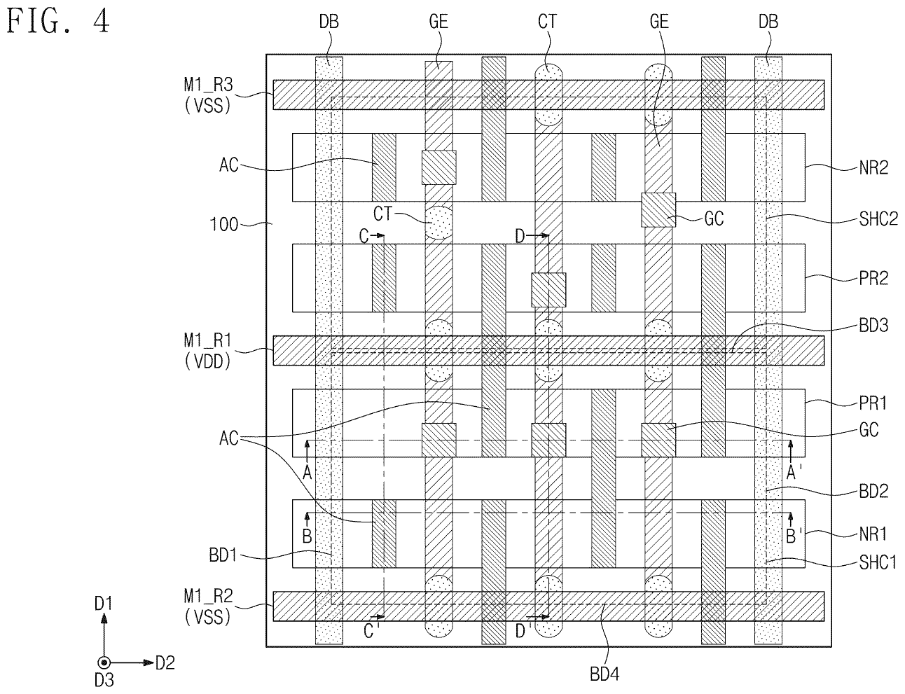

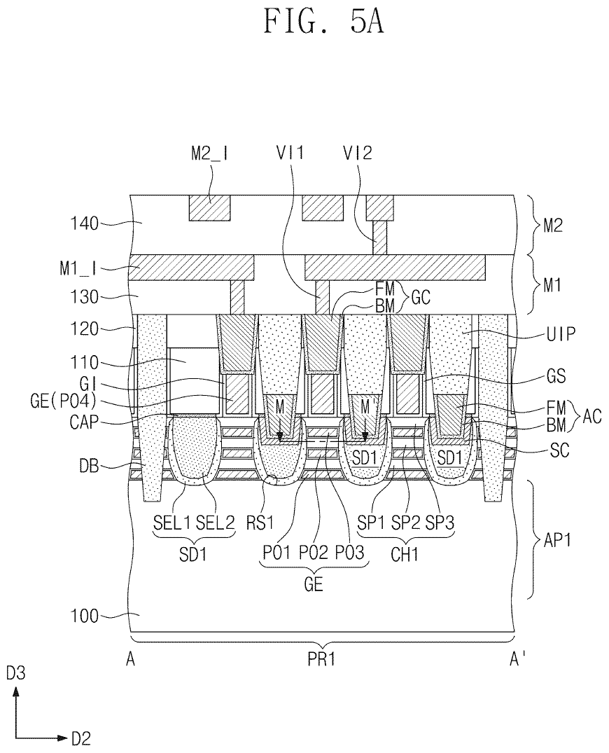

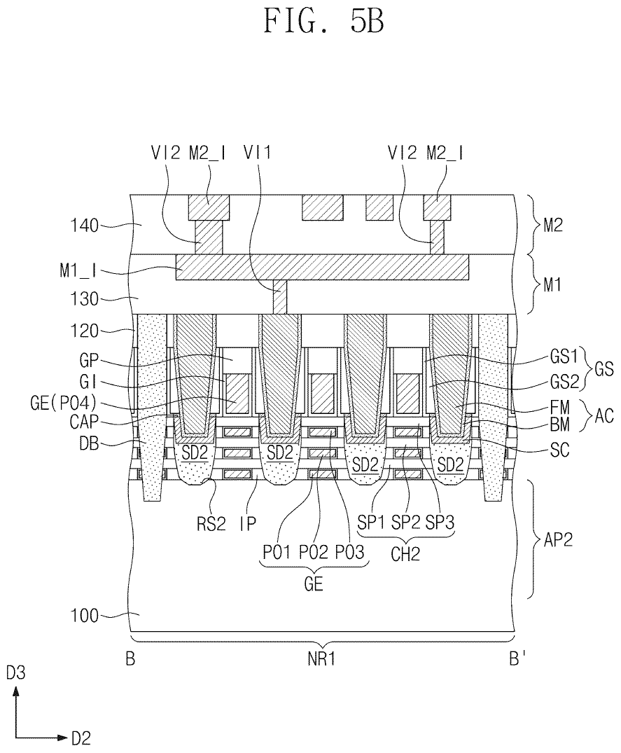

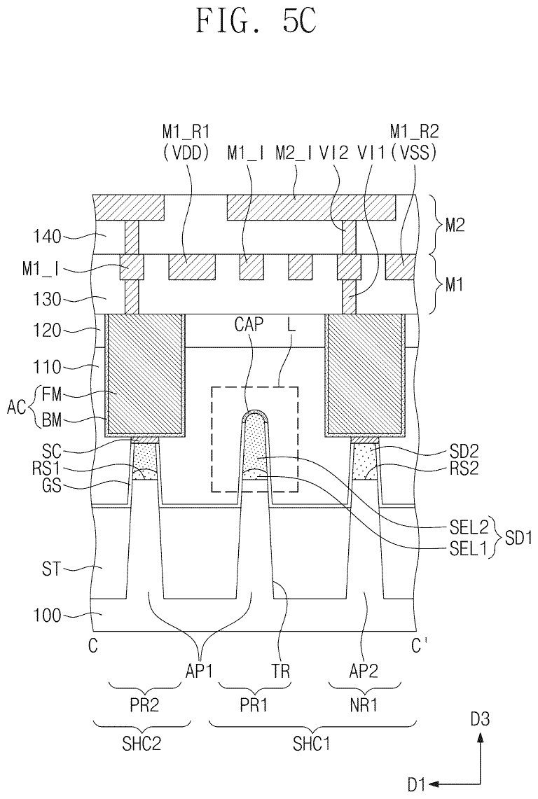

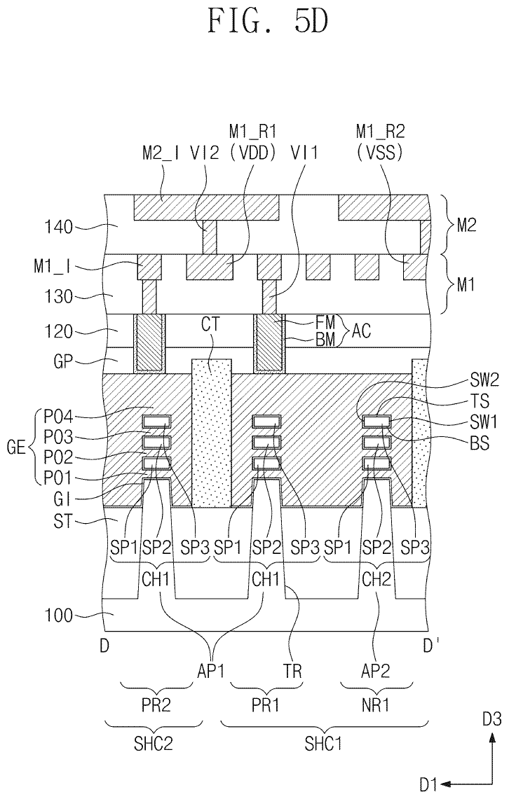

FIG. 4 illustrates a plan view showing a semiconductor device according to an example embodiment of the inventive concepts. FIGS. 5A, 5B, 5C, and 5D illustrate cross-sectional views taken along lines A-A′, B-B′, C-C′, and D-D′ of FIG. 4, respectively. A semiconductor device shown in FIGS. 4 and 5A to 5D is a detailed example of the first and second single height cells SHC1 and SHC2 of FIG. 3.

Referring to FIGS. 4 and 5A to 5D, first and second single height cells SHC1 and SHC2 may be provided on a substrate 100. Each of the first and second single height cells SHC1 and SHC2 may include logic transistors included in a logic circuit. The substrate 100 may be a compound semiconductor substrate or a semiconductor substrate including silicon, germanium, or silicon-germanium. For example, the substrate 100 may be a silicon substrate.

The substrate 100 may have a first PMOSFET region PR1, a second PMOSFET region PR2, a first NMOSFET region NR1, and a second NMOSFET region NR2. Each of the first PMOSFET region PR1, the second PMOSFET region PR2, the first NMOSFET region NR1, and the second NMOSFET region NR2 may extend in a second direction D2. The first single height cell SHC1 may include the first NMOSFET region NR1 and the first PMOSFET region PR1, and the second single height cell SHC2 may include the second PMOSFET region PR2 and the second NMOSFET region NR2.

A first active pattern AP1 and a second active pattern AP2 may be defined by a trench TR formed on an upper portion of the substrate 100. The first active pattern AP1 may be provided on each of the first and second PMOSFET regions PR1 and PR2. The second active pattern AP2 may be provided on each of the first and second NMOSFET regions NR1 and NR2. The first and second active patterns AP1 and AP2 may extend in the second direction D2. The first and second active patterns AP1 and AP2 may be vertically protruding portions of the substrate 100.

A device isolation layer ST may be provided on the substrate 100. The device isolation layer ST may fill the trench TR. The device isolation layer ST may include a silicon oxide layer. The device isolation layer ST may not cover any of first and second channel patterns CH1 and CH2 which will be discussed below.

A first channel pattern CH1 may be provided on the first active pattern AP1. A second channel pattern CH2 may be provided on the second active pattern AP2. Each of the first and second channel patterns CH1 and CH2 may include a first semiconductor pattern SP1, a second semiconductor pattern SP2, and a third semiconductor pattern SP3 that are sequentially stacked. The first, second, and third semiconductor patterns SP1, SP2, and SP3 may be spaced apart from each other in a vertical direction (or a third direction D3).

Each of the first, second, and third semiconductor patterns SP1, SP2, and SP3 may include silicon (Si), germanium (Ge), or silicon-germanium (SiGe). For example, each of the first, second, and third semiconductor patterns SP1, SP2, and SP3 may include crystalline silicon. In an example embodiment of the inventive concepts, the first, second, and third semiconductor patterns SP1, SP2, and SP3 may be stacked nano-sheets.

A plurality of first source/drain patterns SD1 may be provided on the first active pattern AP1. A plurality of first recesses RS1 may be formed on an upper portion of the first active pattern AP1. The first source/drain patterns SD1 may be provided in the first recesses RS1, respectively. The first source/drain patterns SD1 may be impurity regions of a first conductivity type (e.g., n-type). The first channel pattern CH1 may be interposed between a pair of first source/drain patterns SD1. For example, the pair of first source/drain patterns SD1 may be connected to each other through the stacked first, second, and third semiconductor patterns SP1, SP2, and SP3.

A plurality of second source/drain patterns SD2 may be provided on the second active pattern AP2. A plurality of second recesses RS2 may be formed on an upper portion of the second active pattern AP2. The second source/drain patterns SD2 may be provided in the second recesses RS2, respectively. The second source/drain patterns SD2 may be impurity regions of a second conductivity type (e.g., p-type). The second channel pattern CH2 may be interposed between a pair of second source/drain patterns SD2. For example, the pair of second source/drain patterns SD2 may be connected to each other through the stacked first, second, and third semiconductor patterns SP1, SP2, and SP3.

The first and second source/drain patterns SD1 and SD2 may be epitaxial patterns formed by a selective epitaxial growth (SEG) process. For example, each of the first and second source/drain patterns SD1 and SD2 may have a top surface higher than that of the third semiconductor pattern SP3. For another example, at least one of the first and second source/drain patterns SD1 and SD2 may have a top surface at substantially the same level as that of a top surface of the third semiconductor pattern SP3.

The first source/drain patterns SD1 may include a semiconductor element (e.g., SiGe) whose lattice constant is greater than that of a semiconductor element of the substrate 100. Therefore, a pair of first source/drain patterns SD1 may provide the first channel pattern CH1 with a compressive stress. The second source/drain patterns SD2 may include the same semiconductor element (e.g., Si) as that of the substrate 100.

Each of the first source/drain patterns SD1 may include a first semiconductor layer SEL1 and a second semiconductor layer SEL2 on the first semiconductor layer SEL1. With reference back to FIG. 5A, the following will describe a cross-sectional shape in the second direction D2 of the first source/drain pattern SD1.

The first semiconductor layer SEL1 may cover an inner wall of the first recess RS1. The first semiconductor layer SEL1 may have a thickness that decreases in a direction toward an upper portion thereof from a lower portion thereof. For example, a thickness in the third direction D3 of the first semiconductor layer SEL1 on a bottom surface of the first recess RS1 may be greater than a thickness in the second direction D2 of the first semiconductor layer SEL1 on an upper portion of the first recess RS1. The first semiconductor layer SEL1 may be shaped like U along a profile of the first recess RS1.

The second semiconductor layer SEL2 may fill an unoccupied portion of the first recess RS1 filled with the first semiconductor layer SEL1. The second semiconductor layer SEL2 may have a volume greater than that of the first semiconductor layer SEL1. For example, a ratio of the volume of the second semiconductor layer SEL2 to a total volume of the first source/drain pattern SD1 may be greater than a ratio of the volume of the first semiconductor layer SEL1 to a total volume of the first source/drain pattern SD1.

Each of the first and second semiconductor layers SEL1 and SEL2 may include silicon-germanium (SiGe). The first semiconductor layer SEL1 may contain germanium (Ge) whose concentration is relatively low. In some example embodiments of the inventive concepts, the first semiconductor layer SEL1 may include only silicon (Si) and may not include germanium (Ge). The first semiconductor layer SEL1 may have a germanium concentration of about 0 at % to about 10 at %.

The second semiconductor layer SEL2 may contain germanium (Ge) whose concentration is relatively high. For example, the second semiconductor layer SEL2 may have a germanium (Ge) concentration of about 30 at % to about 75 at %. The germanium concentration of the second semiconductor layer SEL2 may gradually increase in the third direction D3. For example, the second semiconductor layer SEL2 adjacent to the first semiconductor layer SEL1 may have a germanium concentration of about 40 at %, but an upper portion of the second semiconductor layer SEL2 may have a germanium concentration of about 60 at %.

The first and second semiconductor layers SEL1 and SEL2 may include impurities (e.g., boron) that cause the first source/drain pattern SD1 to have a p-type. An impurity concentration (e.g., atomic percent) of the second semiconductor layer SEL2 may be greater than that of the first semiconductor layer SEL1.

The first semiconductor layer SEL1 may alleviate or prevent stacking faults between the substrate 100 and the second semiconductor layer SEL2 and between the second semiconductor layer SEL2 and the first, second, and third semiconductor patterns SP1, SP2, and SP3. The occurrence of stacking faults may increase a channel resistance. The stacking faults may easily occur at the bottom surface of the first recess RS1. Accordingly, it may be desirable that a thickness in the third direction D3 of the first semiconductor layer SEL1 adjacent to the bottom surface of the first recess RS1 is larger than a thickness in the second direction D2 of the first semiconductor layer SEL1 on an upper portion of the first recess RS1 to alleviate or prevent the stacking faults.

The first semiconductor layer SEL1 may protect the second semiconductor layer SEL2 while sacrificial layers SAL are replaced with first, second, and third parts PO1, PO2, and PO3 of a gate electrode GE which will be discussed below. For example, the first semiconductor layer SEL1 may alleviate or prevent the second semiconductor layer SEL2 from being etched with an etching material that etches the sacrificial layers SAL.

In some example embodiments, each of the first and second source/drain patterns SD1 and SD2 may have an embossing shape at a sidewall thereof. For example, each of the first and second source/drain patterns SD1 and SD2 may have a wavy profile at the sidewall thereof. The sidewall of each of the first and second source/drain patterns SD1 and SD2 may protrude toward the first, second, and third part PO1, PO2, and PO3 of the gate electrode GE which will be discussed below.

Gate electrodes GE may be provided to extend in a first direction D1, while running across the first and second channel patterns CH1 and CH2. The gate electrodes GE may be arranged at a first pitch in the second direction D2. Each of the gate electrodes GE may vertically overlap the first and second channel patterns CH1 and CH2.

The gate electrode GE may include a first part PO1 interposed between the first semiconductor pattern SP1 and the active pattern AP1 or AP2, a second part PO2 interposed between the first semiconductor pattern SP1 and the second semiconductor pattern SP2, and a third part PO3 interposed between the second semiconductor pattern SP2 and the third semiconductor pattern SP3, and a fourth part PO4 on the third semiconductor pattern SP3.

Referring to FIG. 5A, on the first PMOSFET region PR1, the gate electrode GE may have different widths at the first, second, and third parts PO1, PO2, and PO3 thereof. For example, a maximum width in the second direction D2 of the third part PO3 may be greater than a maximum width in the second direction D2 of the second part PO2. A maximum width in the second direction D2 of the first part PO1 may be greater than the maximum in the second direction D2 of the third part PO3.

Referring to FIG. 5D, the gate electrode GE may be provided on a top surface TS, a bottom surface BS, and opposite sidewalls SW1 and SW2 of each of the first, second, and third semiconductor patterns SP1, SP2, and SP3. For example, a transistor according to the present example embodiment may be a three-dimensional field effect transistor (e.g., Multi-Bridge-Channel Field Effect Transistor (MBCFET) or Gate-All-Around Field Effect Transistor (GAAFET)) in which the gate electrode GE three-dimensionally surrounds a channel or the first and second channel patterns CH1 and CH2.

For example, the first single height cell SHC1 may have a first boundary BD1 and a second boundary BD2 that are opposite to each other in the second direction D2. The first and second boundaries BD1 and BD2 may extend in the first direction D1. The first single height cell SHC1 may have a third boundary BD3 and a fourth boundary BD4 that are opposite to each other in the first direction D1. The third and fourth boundaries BD3 and BD4 may extend in the second direction D2.

Gate cutting patterns CT may be disposed on a boundary in the second direction D2 of each of the first and second single height cells SHC1 and SHC2. For example, the gate cutting patterns CT may be disposed on the third and fourth boundaries BD3 and BD4 of the first single height cell SHC1. The gate cutting patterns CT may be arranged at the first pitch along the third boundary BD3. The gate cutting patterns CT may be arranged at the first pitch along the fourth boundary BD4. When viewed in a plan view, the gate cutting patterns CT on the third and fourth boundaries BD3 and BD4 may be disposed to overlap the gate electrodes GE, respectively. The gate cutting patterns CT may include a dielectric material, such as a silicon oxide layer, a silicon nitride layer, or a combination thereof.

The gate cutting pattern CT may separate the gate electrode GE on the first single height cell SHC1 from the gate electrode GE on the second single height cell SHC2. The gate cutting pattern CT may be interposed between the gate electrode GE on the first single height cell SHC1 and the gate electrode GE on the second single height cell SHC2 that are aligned with each other in the first direction D1. For example, the gate cutting patterns CT may divide the gate electrode GE, which extends in the first direction D1, into a plurality of gate electrodes GE.

Referring to FIG. 4, at least one of the gate cutting patterns CT may not be positioned on a boundary of a cell, but may be positioned within the cell. For example, the gate cutting pattern CT may be located between the second PMOSFET region PR2 and the second NMOSFET region NR2 of the second single height cell SHC2.

Referring to FIGS. 4 and 5A to 5D, a gate spacer GS may be disposed on each of opposite sidewalls of the fourth part PO4 included in the gate electrode GE. The gate spacer GS may extend in the first direction D1 along the gate electrode GE. The gate spacer GS may have a top surface higher than that of the gate electrode GE. The top surface of the gate spacer GS may be coplanar with that of a first interlayer dielectric layer 110, as discussed below. The gate spacers GS may include at least one of SiOCN, AlO, or SiN. In an example embodiment, the gate spacers GS may each include a multi-layer formed of at least two of SiOCN, AlO, or SiN.

A gate capping pattern GP may be provided on the gate electrode GE. The gate capping pattern GP may extend in the first direction D1 along the gate electrode GE. The gate capping pattern GP may include a material having an etch selectivity with respect to first and second interlayer dielectric layers 110 and 120 which will be discussed below. For example, the gate capping pattern GP may include at least one of SiON, SiCN, SiCON, or SiN.

A gate dielectric layer GI may be interposed between the gate electrode GE and the first channel pattern CH1 and between the gate electrode GE and the second channel pattern CH2. The gate dielectric layer GI may cover the top surface TS, the bottom surface BS, and the opposite sidewalls SW1 and SW2 of each of the first, second, and third semiconductor patterns SP1, SP2, and SP3. The gate dielectric layer GI may cover a top surface of the device isolation layer ST that underlies the gate electrode GE (see FIG. 5D).

In an example embodiment of the inventive concepts, the gate dielectric layer GI may include at least one of a silicon oxide layer, a silicon oxynitride layer, or a high-k dielectric layer. The high-k dielectric layer may include a high-k dielectric material whose dielectric constant is greater than that of a silicon oxide layer. For example, the high-k dielectric material may include at least one of hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, or lead zinc niobate.

In some example embodiment, a semiconductor device according to the inventive concepts may include a negative capacitance (NC) field effect transistor (FET) that uses a negative capacitor. For example, the gate dielectric layer GI may include a ferroelectric material layer that exhibits ferroelectric properties and a paraelectric material layer that exhibits paraelectric properties.

The ferroelectric material layer may have a negative capacitance, and the paraelectric material layer may have a positive capacitance. For example, when two or more capacitors are connected in series, and when each capacitor has a positive capacitance, an overall capacitance may be reduced to be less than the capacitance of each capacitor. In contrast, when at least one of two or more capacitors connected in series has a negative capacitance, an overall capacitance may have a positive value that is increased to be greater than an absolute value of the capacitance of each capacitor.

When the ferroelectric material layer having a negative capacitance is connected in series to the paraelectric material layer having a positive capacitance, there may be an increase in overall capacitance of the ferroelectric and paraelectric material layers that are connected in series. The increase in overall capacitance may be used to allow a transistor including the ferroelectric material layer to have a sub-threshold swing of less than about 60 mV/decade at room temperature.

The ferroelectric material layer may have ferroelectric properties. The ferroelectric material layer may include, for example, at least one of hafnium oxide, hafnium zirconium oxide, barium strontium titanium oxide, or lead zirconium titanium oxide. For example, the hafnium zirconium oxide may be a material in which hafnium oxide is doped with zirconium (Zr). For another example, the hafnium zirconium oxide may be a compound of hafnium (Hf), zirconium (Zr), and oxygen (O).

The ferroelectric material layer may further include impurities doped therein. For example, the impurities may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), or tin (Sn). The type of impurities included in the ferroelectric material layer may be changed depending on what ferroelectric material is included in the ferroelectric material layer.

When the ferroelectric material layer includes hafnium oxide, the ferroelectric material layer may include at least one of as gadolinium (Gd), silicon (Si), zirconium (Zr), aluminum (Al), or yttrium (Y), as impurities.

When the impurities are aluminum (Al), the ferroelectric material layer may include about 3 to 8 atomic percent aluminum. In this description, the ratio of impurities may be a ratio of aluminum to the sum of hafnium and aluminum.

When the impurities are silicon (Si), the ferroelectric material layer may include about 2 to about 10 atomic percent silicon. When the impurities are yttrium (Y), the ferroelectric material layer may include about 2 to about 10 atomic percent yttrium. When the impurities are gadolinium (Gd), the ferroelectric material layer may include about 1 to about 7 atomic percent gadolinium. When the impurities are zirconium (Zr), the ferroelectric material layer may include about 50 to about 80 atomic percent zirconium.

The paraelectric material layer may have paraelectric properties. The paraelectric material layer may include, for example, at least one of silicon oxide or high-k metal oxide. The metal oxide included in the paraelectric material layer may include, for example, at least one of hafnium oxide, zirconium oxide, or aluminum oxide, but the inventive concepts are not limited thereto.

The ferroelectric and paraelectric material layers may include the same material. The ferroelectric material layer may have ferroelectric properties, but the paraelectric material layer may not have ferroelectric properties. For example, when the ferroelectric material layer and the paraelectric material layer include hafnium oxide, the hafnium oxide included in the ferroelectric material layer may have a crystal structure different from that of the hafnium oxide included in the paraelectric material layer.

The ferroelectric material layer may have a thickness having ferroelectric properties. The thickness of the ferroelectric material layer may range, for example, from about 0.5 nm to about 10 nm, but the inventive concepts are not limited thereto. Because ferroelectric materials have their own critical thickness that exhibits ferroelectric properties, the thickness of the ferroelectric material layer may depend on ferroelectric material.

For example, the gate dielectric layer GI may include a single ferroelectric material layer. For another example, the gate dielectric layer GI may include a plurality of ferroelectric material layers that are spaced apart from each other. The gate dielectric layer GI may have a stack structure in which a plurality of ferroelectric material layers are alternately stacked with a plurality of paraelectric material layers.

Although not shown, the gate electrode GE may include a first metal pattern and a second metal pattern on the first metal pattern. The first metal pattern may be provided on the gate dielectric layer GI and may be adjacent to the first, second, and third semiconductor patterns SP1, SP2, and SP3. The first metal pattern may include a work-function metal that controls a threshold voltage of a transistor. A thickness and composition of the first metal pattern may be adjusted to achieve a desired threshold voltage of a transistor. For example, the first, second, and third parts PO1, PO2, and PO3 of the gate electrode GE may be formed of the first metal pattern or a work-function metal.

The first metal pattern may include a metal nitride layer. For example, the first metal pattern may include nitrogen (N) and at least one of titanium (Ti), tantalum (Ta), aluminum (Al), tungsten (W), or molybdenum (Mo). In addition, the first metal pattern may further include carbon (C). The first metal pattern may include a plurality of stacked work-function metal layers.

The second metal pattern may include metal whose resistance is less than that of the first metal pattern. For example, the second metal pattern may include at least of tungsten (W), aluminum (Al), titanium (Ti), or tantalum (Ta). For example, the fourth part PO4 of the gate electrode GE may include a first metal pattern and a second metal pattern on the first metal pattern.

Referring to FIG. 5B, inner spacers IP may be provided on the first and second NMOSFET regions NR1 and NR2. The inner spacers IP may be interposed between the second source/drain pattern SD2 and the first, second, and third parts PO1, PO2, and PO3 of the gate electrode GE, respectively. The inner spacers IP may be in direct contact with the second source/drain pattern SD2. The inner spacer IP may separate the second source/drain pattern SD2 from each of the first, second, and third parts PO1, PO2, and PO3 of the gate electrode GE.

A first interlayer dielectric layer 110 may be provided on the substrate 100. The first interlayer dielectric layer 110 may cover the gate spacers GS and the first and second source/drain patterns SD1 and SD2. The first interlayer dielectric layer 110 may have a top surface substantially coplanar with that of the gate capping pattern GP and that of the gate spacer GS. The first interlayer dielectric layer 110 may be provided thereon with a second interlayer dielectric layer 120 that covers the gate capping pattern GP. A third interlayer dielectric layer 130 may be provided on the second interlayer dielectric layer 120. A fourth interlayer dielectric layer 140 may be provided on the third interlayer dielectric layer 130. For example, the first to fourth interlayer dielectric layers 110 to 140 may include a silicon oxide layer.

The single height cell SHC may have a first boundary BD1 and a second boundary BD2 that are opposite to each other in the second direction D2. The first and second boundaries BD1 and BD2 may extend in the first direction D1. The single height cell SHC may have a third boundary BD3 and a fourth boundary BD4 that are opposite to each other in the first direction D1. The third and fourth boundaries BD3 and BD4 may extend in the second direction D2.

Each of the first and second single height cells SHC1 and SHC2 may be provided on its opposite sides with a pair of separation structures DB that are opposite to each other in the second direction D2. For example, the pair of separation structures DB may be provided on the first and second boundaries BD1 and BD2 of the first single height cell SHC1, respectively. The separation structure DB may extend in the first direction D1 parallel to the gate electrodes GE. A pitch between the separation structure DB and its adjacent gate electrode GE may be the same as the first pitch.

The separation structure DB may penetrate the first and second interlayer dielectric layers 110 and 120 to extend into the first and second active patterns AP1 and AP2. The separation structure DB may penetrate an upper portion of each of the first and second active patterns AP1 and AP2. The separation structure DB may electrically separate an active region of each of the first and second single height cells SHC1 and SHC2 from an active region of another cell.

Active contacts AC may penetrate the first and second interlayer dielectric layers 110 and 120 to come into electrical connection with the first and second source/drain patterns SD1 and SD2. A pair of active contacts AC may be provided on opposite sides of the gate electrode GE. When viewed in a plan view, the active contact AC may have a bar shape that extends in the first direction D1.

The active contact AC may be a self-aligned contact. For example, the gate capping pattern GP and the gate spacer GS may be used to form the active contact AC in a self-alignment manner. The active contact AC may cover, for example, at least a portion of a sidewall of the gate spacer GS. Although not shown, the active contact AC may cover a portion of the top surface of the gate capping pattern GP.

Silicide patterns SC may be interposed between the active contact AC and the first source/drain pattern SD1 and between the active contact AC and the second source/drain pattern SD2, respectively. The active contact AC may be electrically connected through the silicide pattern SC to the source/drain pattern SD1 or SD2. The silicide pattern SC may include metal silicide, for example, at least one of titanium silicide, tantalum silicide, tungsten silicide, nickel silicide, or cobalt silicide.

Gate contacts GC may penetrate the second interlayer dielectric layer 120 and the gate capping pattern GP to come into electrical connection with the gate electrodes GE. When viewed in a plan view, the gate contacts GC on the first single height cell SHC1 may overlap the first PMOSFET region PR1. For example, the gate contacts GC on the first single height cell SHC1 may be provided on the first active pattern AP1 (see FIG. 5A).

The gate contact GC may be freely located with no limitation of position on the gate electrode GE. For example, the gate contacts GC on the second single height cell SHC2 may be disposed on the second PMOSFET region PR2, the second NMOSFET region NR2, and the device isolation layer ST that fills the trench TR, respectively (see FIG. 4).

In an example embodiment of the inventive concepts, referring to FIG. 5A, the active contact AC may have an upper portion adjacent to the gate contact GC, and the upper portion of the gate contact GC may be filled with an upper dielectric pattern UIP. The upper dielectric pattern UIP may have a bottom surface lower than that of the gate contact GC. For example, the upper dielectric pattern UIP may cause the active contact AC adjacent to the gate contact GC to have a top surface lower than the bottom surface of the gate contact GC. Therefore, it may be possible to alleviate or prevent a short circuit resulting from contact between the gate contact GC and its adjacent active contact AC.

Each of the active contact AC and the gate contact GC may include a conductive pattern FM and a barrier pattern BM that surrounds the conductive pattern FM. For example, the conductive pattern FM may include at least one of aluminum, copper, tungsten, molybdenum, or cobalt. The barrier pattern BM may cover sidewalls and a bottom surface of the conductive pattern FM. The barrier pattern BM may include a metal layer and a metal nitride layer. The metal layer may include at least one of titanium, tantalum, tungsten, nickel, cobalt, or platinum. The metal nitride layer may include at least one of a titanium nitride (TiN) layer, a tantalum nitride (TaN) layer, a tungsten nitride (WN) layer, a nickel nitride (NiN) layer, a cobalt nitride (CON) layer, or a platinum nitride (PtN) layer.

A first metal layer M1 may be provided in the third interlayer dielectric layer 130. For example, the first metal layer M1 may include a first power line M1_R1, a second power line M1_R2, a third power line M1_R3, and first wiring lines M1_I. The lines M1_R1, M1_R2, M1_R3, and M1_I of the first metal layer M1 may extend in parallel in the second direction D2.

For example, the first and second power lines M1_R1 and M1_R2 may be provided on the third and fourth boundaries BD3 and BD4 of the first single height cell SHC1, respectively. The first power line M1_R1 may extend in the second direction D2 along the third boundary BD3. The second power line M1_R2 may extend in the second direction D2 along the fourth boundary BD4.

The first wiring lines M1_I of the first metal layer M1 may be arranged at a second pitch along the first direction D1. The second pitch may be less than the first pitch of the gate electrodes GE. Each of the first wiring lines M1_I may have a line-width less than that of each of the first, second, and third power lines M1_R1, M1_R2, and M1_R3.

The first metal layer M1 may further include first vias VI1. The first vias VI1 may be provided below the lines M1_R1, M1_R2, M1_R3, and M1_I of the first metal layer M1, respectively. The first via VI1 may electrically connect the active contact AC to a certain line of the first metal layer M1. The first via VI1 may electrically connect the gate contact GC to a wiring line of the first metal layer M1.

A certain line and its underlying first via VI1 of the first metal layer M1 may be formed by individual processes. For example, the certain line and its underlying first via VI1 of the first metal layer M1 may each be formed by a single damascene process. A sub-20 nm process may be employed to fabricate a semiconductor device according to the present example embodiment.

A second metal layer M2 may be provided in the fourth interlayer dielectric layer 140. The second metal layer M2 may include a plurality of second wiring lines M2_I. The second wiring lines M2_I of the second metal layer M2 may each have a linear or bar shape that extends in the first direction D1. For example, the second wiring lines M2_I may extend in parallel in the first direction D1.

The second metal layer M2 may further include second vias VI2 that are provided below the second wiring lines M2_I, respectively. A certain line of the first metal layer M1 may be electrically connected, through the second via VI2, to a corresponding line of the second metal layer M2. A wiring line and its underlying second via VI2 of the second metal layer M2 may be simultaneously formed by a dual damascene process.

The first and second metal layers M1 and M2 may have their wiring lines that include the same or different conductive (e.g., metallic) materials. For example, the wiring line of the first metal layer M1 and the wiring line of the second metal layer M2 may include at least one of aluminum, copper, tungsten, ruthenium, molybdenum, or cobalt. Although not shown, other metal layers (e.g., M3, M4, M5, etc.) may be additionally stacked on the fourth interlayer dielectric layer 140. Each of the stacked metal layers may include wiring lines for routing between cells.

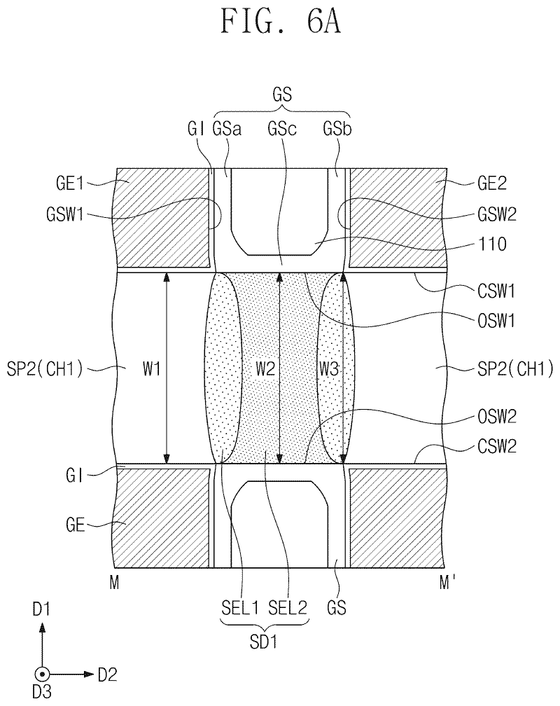

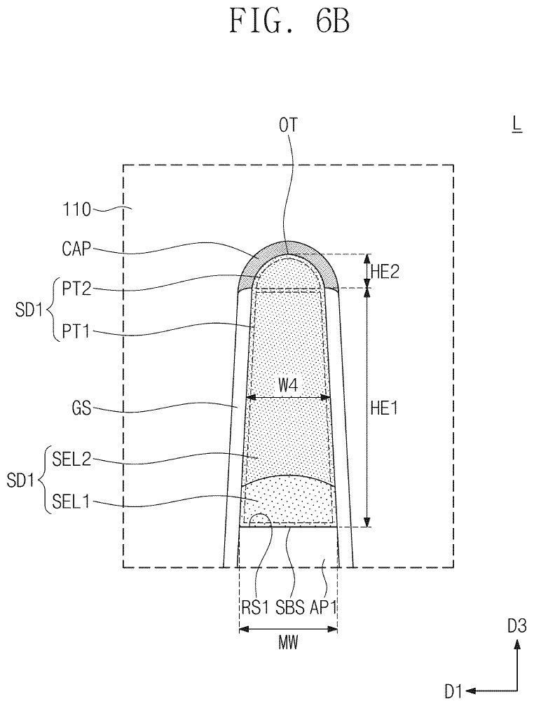

FIG. 6A illustrate a top view taken along line M-M′ of FIG. 5A. FIG. 6B illustrates an enlarged view showing an example embodiment of section L depicted in FIG. 5C. With reference to FIGS. 6A and 6B, the following will describe in detail the first source/drain pattern SD1 and the gate spacer GS that covers the first source/drain pattern SD1.

The first source/drain pattern SD1 may be provided on the first active pattern AP1. For example, the first active pattern AP1 may be recessed to define the first recess RS1, and the first source/drain pattern SD1 may be formed in the first recess RS1. The first active pattern AP1 may have a fin shape.

Referring to FIG. 6A, the first source/drain pattern SD1 may be adjacent in the second direction D2 to the second semiconductor pattern SP2. The first source/drain pattern SD1 may be interposed between a pair of second semiconductor patterns SP2 that are adjacent to each other in the second direction D2. The first source/drain pattern SD1 may include a first semiconductor layer SEL1 adjacent to a pair of second semiconductor patterns SP2 and a second semiconductor layer SEL2 at a center of the first source/drain pattern SD1. The first semiconductor layer SEL1 of the first source/drain pattern SD1 may be in direct contact with the second semiconductor pattern SP2 of the first source/drain pattern SD1.

The second semiconductor pattern SP2 may have a first sidewall CSW1 and a second sidewall CSW2 that are opposite to each other in the first direction D1. The first and second sidewalls CSW1 and CSW2 may be covered with the gate dielectric layer GI. The gate electrode GE may be adjacent to the first and second sidewalls CSW1 and CSW2 through the gate dielectric layer GI.

The first source/drain pattern SD1 may have a first outer sidewall OSW1 and a second outer sidewall OSW2. The first outer sidewall OSW1 and the second outer sidewall OSW2 may be opposite to each other in the first direction D1. The first outer sidewall OSW1 may be substantially coplanar with the first sidewall CSW1 of the second semiconductor pattern SP2. The second outer sidewall OSW2 may be substantially coplanar with the second sidewall CSW2 of the second semiconductor pattern SP2.

The gate spacer GS may be interposed between a first gate electrode GE1 and a second gate electrode GE2 that are adjacent to each other in the second direction D2. The first gate electrode GE1 may have a first gate sidewall GSW1. The second gate electrode GE2 may have a second gate sidewall GSW2. The first and second gate sidewalls GSW1 and GSW2 each may extend in the first direction D1. The first and second gate sidewalls GSW1 and GSW2 may be opposite to each other in the second direction D2. The first and second gate sidewalls GSW1 and GSW2 may be covered with the gate dielectric layer GI. The first and second gate sidewalls GSW1 and GSW2 may be adjacent to the first outer sidewall OSW1 of the first source/drain pattern SD1.

The gate spacer GS may cover the first gate sidewall GSW1 of the first gate electrode GE1, the second gate sidewall GSW2 of the second gate electrode GE2, and the first outer sidewall OSW1 of the first source/drain pattern SD1. For example, the gate spacer GS may include a first part GSa that covers the first gate sidewall GSW1, a second part GSb that covers the second gate sidewall GSW2, and a third part GSc that covers the first outer sidewall OSW1.

The third part GSc may be a portion that extends along the second direction D2 from the first part GSa to the second part GSb. The first source/drain pattern SD1 may be spaced apart from the first interlayer dielectric layer 110 across the third part GSc.

The first source/drain pattern SD1 may have a first width W1 that is a maximum width in the first direction D1. The second semiconductor pattern SP2 may have a second width W2 that is a maximum width in the first direction D1. The first width W1 and the second width W2 may be values measured at the same vertical height. A ratio of the second width W2 to the first width W1 may range from about 0.9 to about 1.1. The first width W1 may be substantially the same as the second width W2.

A third width W3 may refer to a maximum width in the first direction D1 of the first semiconductor layer SEL1. The third width W3 and the second width W2 may be values measured at the same vertical height. A ratio of the second width W2 to the third width W3 may range from about 0.9 to about 1.1. The third width W3 may be substantially the same as the second width W2.

The gate spacer GS may cover the second outer sidewall OSW2 of the first source/drain pattern SD1. The first and second outer sidewalls OSW1 and OSW2 may be in direct contact with their adjacent gate spacer GS. The first width W1 of the first source/drain pattern SD1 may be a minimum distance in the first direction D1 between the gate spacers GS that cover the first and second outer sidewalls OSW1 and OSW2, respectively.

Referring to FIG. 6B, the first source/drain pattern SD1 may have a fourth width W4 in the first direction D1. The fourth width W4 may have a maximum value at a bottom surface SBS of the first source/drain pattern SD1. The fourth width W4 may decrease with increasing distance in the vertical direction (or the third direction D3) from the bottom surface SBS of the first source/drain pattern SD1.

The first source/drain pattern SD1 may include a first part PT1 in (e.g., within or surrounded by) the gate spacer GS and a second part PT2 on the first part PT1. A top surface OT of the second part PT2 may have a curvature. The second part PT2 may have an average width less than that of the first part PT1.

A silicon cap CAP may be provided on the second part PT2. The silicon cap CAP may cover the first source/drain pattern SD1 exposed by the gate spacer GS. The silicon cap CAP may have an average thickness the same as or less than that of the gate spacer GS.

A first height HE1 may refer to a maximum height in the vertical direction D3 of the first part PT1. A second height HE2 may refer to a maximum height in the vertical direction D3 of the second part PT2. The first height HE1 may be greater than the second height HE2.

Referring to FIG. 5C, a maximum level (e.g., a highest or top level) of the gate spacer GS may be higher than a level of a bottom surface of the active contact AC. Alternatively, the maximum level (e.g., a highest level) of the gate spacer GS may be higher than a level of the bottom surface BS of the third semiconductor pattern SP3.

The gate spacer GS on the first and second PMOSFET regions PR1 and PR2 may have a configuration and a thickness substantially the same as those of the gate spacer GS on the first and second NMOSFET regions NR1 and NR2.

According to some example embodiments of the inventive concepts, a maximum width in the first direction D1 of each of the first and second source/drain patterns SD1 and SD2 may be substantially the same as a maximum width in the first direction D1 of each of the first, second, and third semiconductor patterns SP1, SP2, and SP3. The gate spacer GS may be formed at a large height (e.g., a greatest height) on the sidewall of each of the first and second source/drain patterns SD1 and SD2. It may thus be possible to control the degree of growth in the first direction D1 of the first and second source/drain patterns SD1 and SD2.

The first and second source/drain patterns SD1 and SD2 may have their widths that decrease with increasing distance in the vertical direction from bottom surfaces of the first and second source/drain patterns SD1 and SD2. As the first and second source/drain patterns SD1 and SD2 have their fin shapes, it may be possible to alleviate or prevent a short circuit caused by contact between neighboring ones of the first and second source/drain patterns SD1 and SD2. Thus, the inventive concepts may achieve an improvement in reliability and electrical properties of devices.

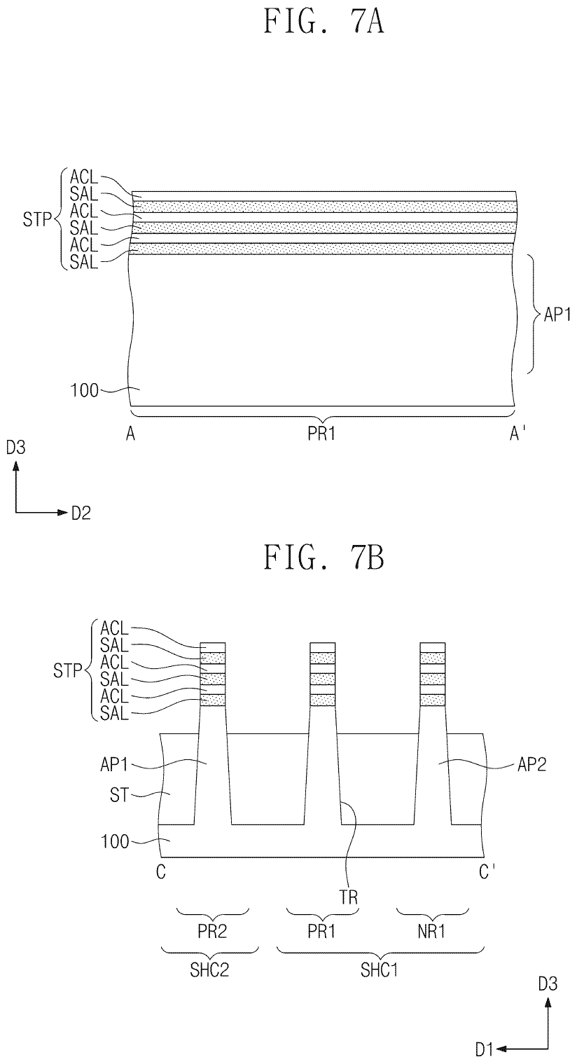

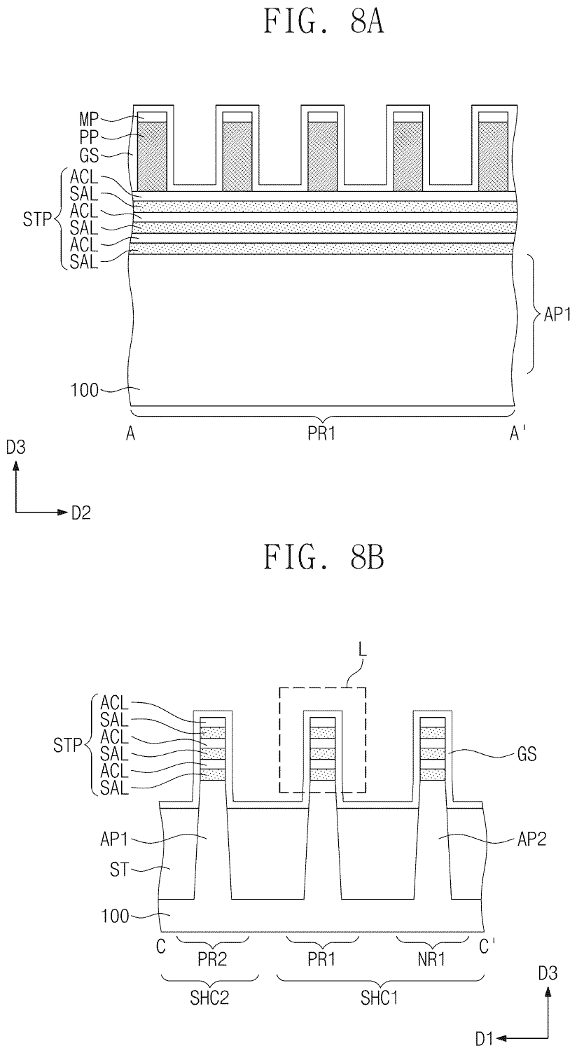

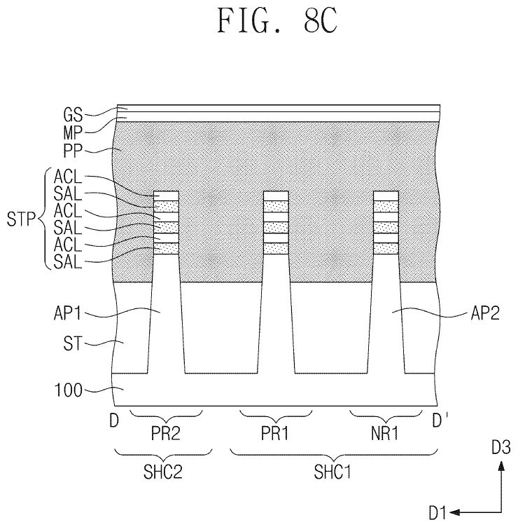

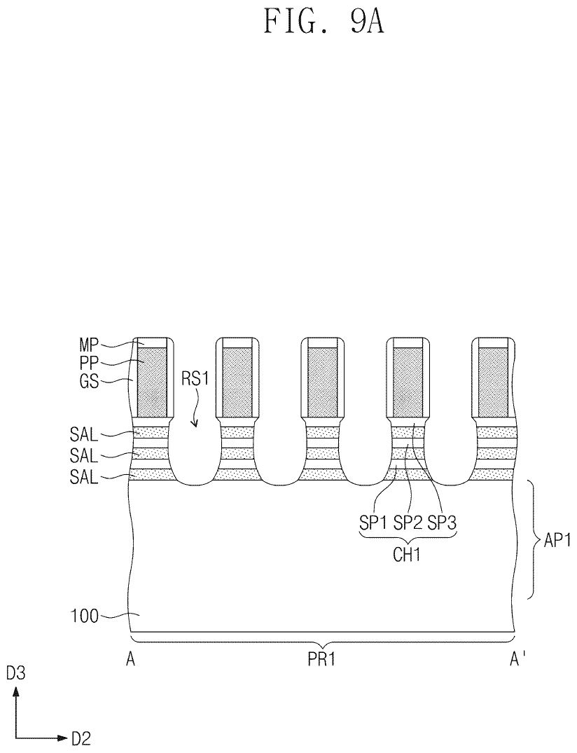

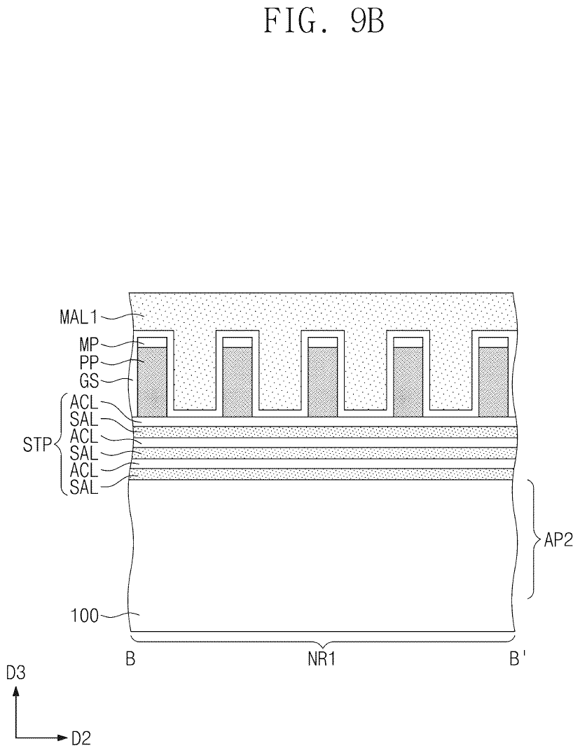

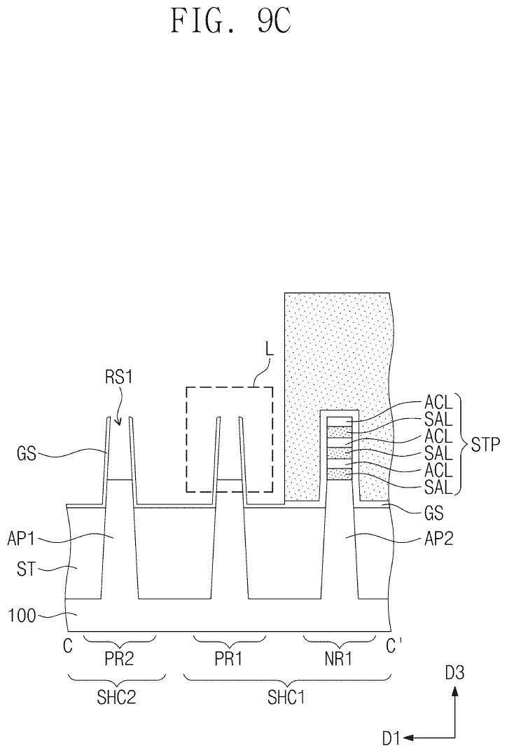

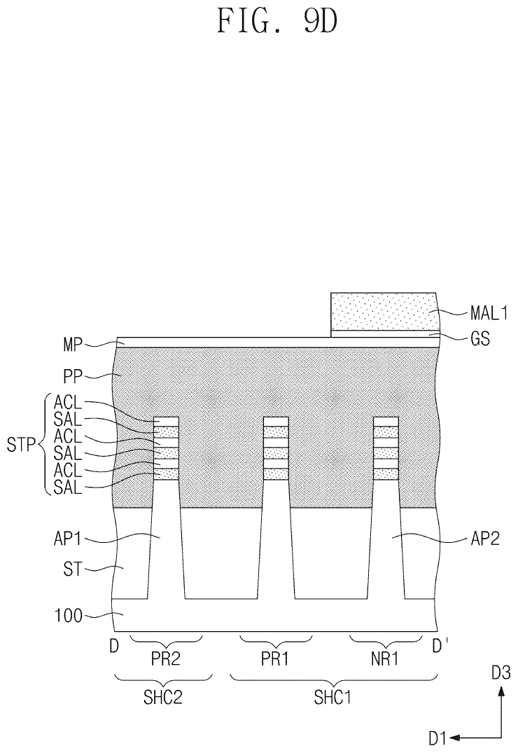

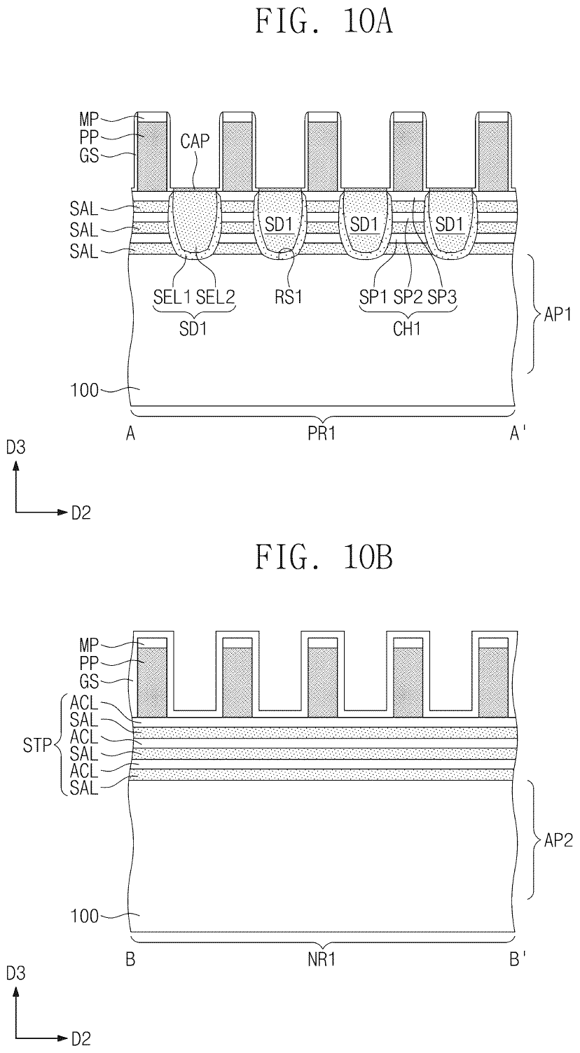

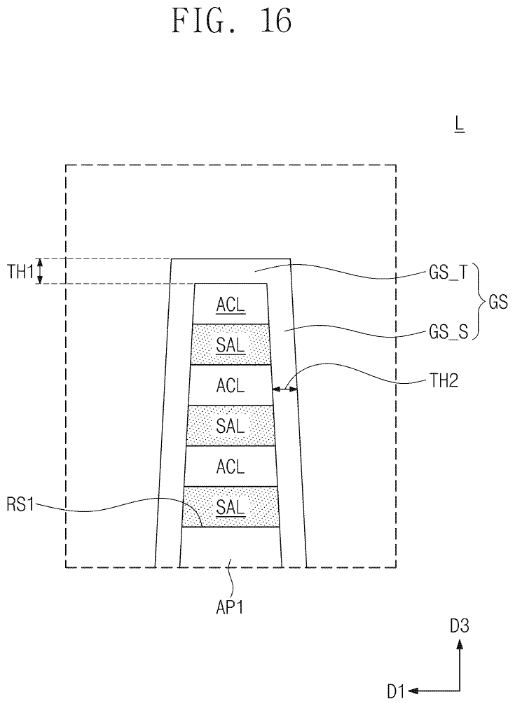

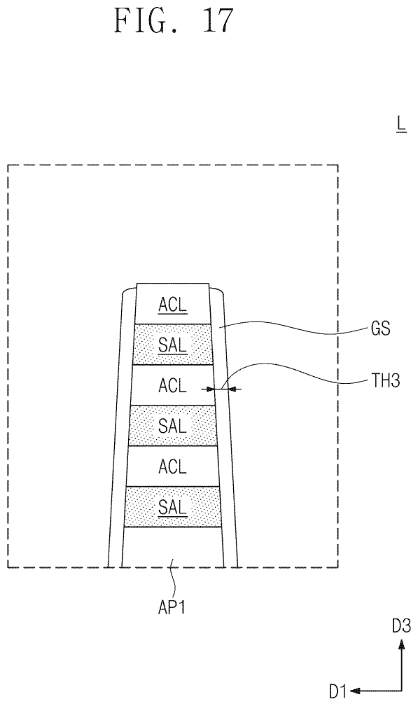

FIGS. 7A to 15D illustrate cross-sectional views showing a method of fabricating a semiconductor device according to an example embodiment of the inventive concepts. For example, FIGS. 7A, 8A, 9A, 10A, 11a, 12A, 13A, 14A, and 15A illustrate cross-sectional views taken along line A-A′ of FIG. 4. FIGS. 9B, 10B, 11B, 12B, 13B, 14B, and 15B illustrate cross-sectional views taken along line B-B′ of FIG. 4. FIGS. 7B, 8B, 9C, 10C, 11C, 12C, 13C, 14C, and 15C illustrate cross-sectional views taken along line C-C′ of FIG. 4. FIGS. 8C, 9D, 13D, 14D, and 15D illustrate cross-sectional views taken along line D-D′ of FIG. 4. FIG. 16 illustrates an enlarged view showing section L of FIG. 8B. FIGS. 17 and 18 illustrate enlarged views showing a method of forming section L depicted in FIG. 9C.

Referring to FIGS. 7A and 7B, a substrate 100 may be provided which includes first and second PMOSFET regions PR1 and PR2 and first and second NMOSFET regions NR1 and NR2. Sacrificial layers SAL and active layers ACL may be alternately stacked on the substrate 100. The sacrificial layers SAL may include one of silicon (Si), germanium (Ge), and silicon-germanium (SiGe), and the active layers ACL may include one of silicon (Si), germanium (Ge), and silicon-germanium (SiGe).

For example, the sacrificial layers SAL may include silicon-germanium (SiGe), and the active layers ACL may include silicon (Si). Each of the sacrificial layers SAL may have a germanium concentration of about 10 at % to about 30 at %.

Mask patterns may be formed on the first and second PMOSFET regions PR1 and PR2 and the first and second NMOSFET regions NR1 and NR2 of the substrate 100, respectively. The mask pattern may have a linear or bar shape that extends in a second direction D2.

A patterning process may be performed in which the mask patterns are used as an etching mask to form a trench TR that defines a first active pattern AP1 and a second active pattern AP2. The first active pattern AP1 may be formed on each of the first and second PMOSFET regions PR1 and PR2. The second active pattern AP2 may be formed on each of the first and second NMOSFET regions NR1 and NR2.

A stack pattern STP may be formed on each of the first and second active patterns AP1 and AP2. The stack pattern STP may include the sacrificial layers SAL and the active layers ACL that are alternately stacked. While the patterning process is performed on the sacrificial layers SAL and the active layers ACL, the first and second active patterns AP1 and AP2 may be formed by etching the stack pattern STP.

A device isolation layer ST may be formed to fill the trench TR. For example, a dielectric layer may be formed on a front surface of the substrate 100 to cover the stack patterns STP and the first and second active patterns AP1 and AP2. The dielectric layer may be recessed until the stack patterns STP are exposed, and thus the device isolation layer ST may be formed.

The device isolation layer ST may include a dielectric material, such as a silicon oxide layer. The stack patterns STP may be exposed upwardly from the device isolation layer ST. For example, the stack patterns STP may vertically protrude upwards from the device isolation layer ST.

Referring to FIGS. 8A to 8C, sacrificial patterns PP may be formed on the substrate 100 to run across the stack patterns STP. Each of the sacrificial patterns PP may be formed to have a linear or bar shape that extends in a first direction D1. The sacrificial patterns PP may be arranged at a second pitch along the second direction D2.

For example, the formation of the sacrificial patterns PP may include forming a sacrificial layer on the front surface of the substrate 100, forming hard mask patterns MP on the sacrificial layer, and using the hard mask patterns MP as an etching mask to pattern the sacrificial layer. The sacrificial layer may include at least one of amorphous silicon or polysilicon.

A gate spacer GS may be formed on the sacrificial patterns PP. The formation of the gate spacers GS may include conformally forming a gate spacer layer on the front surface of the substrate 100 and anisotropically etching the gate spacer layer. The gate spacer layer may include a material having an etch selectivity with respect to silicon (Si). For example, the gate spacer layer may include at least one of SiOCN, AlO, or SiN. For another example, the gate spacer layer may be a multi-layer including at least two selected from SiOCN, AlO, and SiN.

Referring to FIGS. 8A and 16, the gate spacer GS may cover opposite sidewalls of the sacrificial pattern PP. The gate spacer GS may cover a top surface of the device isolation layer ST and a surface of the stack pattern STP. For example, the gate spacer GS may include a spacer top part GS_T that covers a top surface of the stack pattern STP and a spacer side part GS_S that covers a sidewall of the stack pattern STP.

The spacer top part GS_T may have a first thickness TH1. The spacer side part GS_S may have a second thickness TH2. The first thickness TH1 may be a length in a vertical direction D3 of the spacer top part GS_T. The second thickness TH2 may be a length in the first direction D1 of the spacer side part GS_S. The first thickness TH1 may be substantially the same as or greater than the second thickness TH2.

Referring to FIGS. 9A to 9D, a first mask layer MAL1 may be formed on the first and second NMOSFET regions NR1 and NR2 of the substrate 100. For example, the first mask layer MAL1 may include an amorphous carbon layer. The first mask layer MAL1 may expose the first and second PMOSFET regions PR1 and PR2.

The first mask layer MAL1 may be used as an etching mask to etch the stack pattern STP between the sacrificial patterns PP on the first active pattern AP1, thereby forming a first recess RS1. The formation of the first recess RS1 may include using the hard mask pattern MP and the gate spacer GS as an etching mask to etch the stack pattern STP of the first active pattern AP1. The first recess RS1 may be formed between a pair of sacrificial patterns PP.

Referring to FIG. 17, while the first recess RS1 is formed, an upper portion of the gate spacer GS on the first and second PMOSFET regions PR1 and PR2 may also be removed and recessed. For example, the spacer top part GS_T may be removed to expose a top surface of the active layer ACL of the stack pattern STP.

While the first recess RS1 is formed, the gate spacer GS on the sidewall of the stack pattern STP may also be partially recessed. For example, a thickness in the first direction D1 of the spacer side part GS_S may be reduced from the second thickness TH2 to a third thickness TH3. The third thickness TH3 may be less than the second thickness TH2. In some example embodiments, the third thickness TH3 may increase with increasing distance from a top surface of the gate spacer GS.

Referring to FIG. 9C, the gate spacer GS on the first and second PMOSFET regions PR1 and PR2 may have an average thickness less than that of the gate spacer GS on the first and second NMOSFET regions NR1 and NR2.

Referring to FIG. 18, the stack pattern STP may be removed between the sacrificial patterns PP on the first active pattern AP1. While the stack pattern STP is removed, the gate spacer GS may not be removed. This may be caused by the fact that the gate spacer GS includes a material having an etch selectivity with respect to the active layer ACL and the sacrificial layer SAL.

The gate spacer GS may not be removed, but may remain in the first recess RS1. The first recess RS1 may have a first recess width RSW that is a width in the first direction D1. The first recess width RSW may decrease with increasing distance in the vertical direction D3 from a bottom surface of the first recess RS1. The first recess width RSW may be a distance between the gate spacers GS that are spaced apart from each other in the first direction D1.

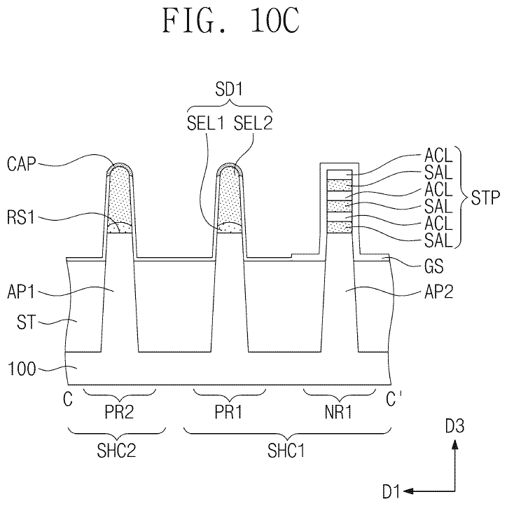

Referring to FIGS. 10A to 10C, the active layers ACL on the first active pattern AP1 may be formed into first, second, and third semiconductor patterns SP1, SP2, and SP3 that are sequentially stacked between neighboring first recesses RS1. A first channel pattern CH1 may be constituted by the first, second, and third semiconductor patterns SP1, SP2, and SP3 between neighboring first recesses RS1.

The first mask layer MAL1 may be selectively removed. Afterwards, first source/drain patterns SD1 may be formed in the first recesses RS1, respectively. For example, a first selective epitaxial growth (SEG) process may be performed in which an inner wall of the first recess RS1 is used as a seed layer to form a first semiconductor layer SEL1. The first, second, and third semiconductor patterns SP1, SP2, and SP3 and the substrate 100 that are exposed to the first recess RS1 may be used as a seed from which the first semiconductor layer SEL1 is grown. For example, the first SEG process may include chemical vapor deposition (CVD) or molecular beam epitaxy (MBE).

The first semiconductor layer SEL1 may include a semiconductor element (e.g., SiGe) whose lattice constant is greater than that of a semiconductor element of the substrate 100. The first semiconductor layer SEL1 may contain germanium (Ge) whose concentration is relatively low. In some example embodiments of the inventive concepts, the first semiconductor layer SEL1 may include only silicon (Si) and may not include germanium (Ge). The first semiconductor layer SEL1 may have a germanium concentration of about 0 at % to about 10 at %.

The first semiconductor layer SEL1 may undergo a second selective epitaxial growth (SEG) process to form a second semiconductor layer SEL2. The second semiconductor layer SEL2 may be formed to completely fill the first recess RS1. The second semiconductor layer SEL2 may contain germanium (Ge) whose concentration is relatively high. For example, the second semiconductor layer SEL2 may have a germanium concentration of about 30 at % to about 70 at %.

The first semiconductor layer SEL1 and the second semiconductor layer SEL2 may constitute the first source/drain pattern SD1. Impurities may be in-situ implanted during the first and second SEG processes. In some example embodiments, after the first source/drain pattern SD1 is formed, impurities may be doped into the first source/drain pattern SD1. The first source/drain pattern SD1 may be doped to have a first conductivity type (e.g., p-type).

The gate spacer GS may cause the first source/drain pattern SD1 to grow to have a fin shape. The first recess width RSW of FIG. 18 may cause that a width in the first direction D1 of the first source/drain pattern SD1 decreases with increasing distance in the vertical direction D3 from the bottom surface of the first recess RS1. As the first and second NMOSFET regions NR1 and NR2 are covered with the gate spacer GS during the first and second SEG processes, no semiconductor layer may be separately grown.

A silicon cap CAP may be formed on the first source/drain pattern SD1. For example, the silicon cap CAP may cover a top surface at an upper portion of the first source/drain pattern SD1. The silicon cap CAP may be formed on the top surface of the gate spacer GS.

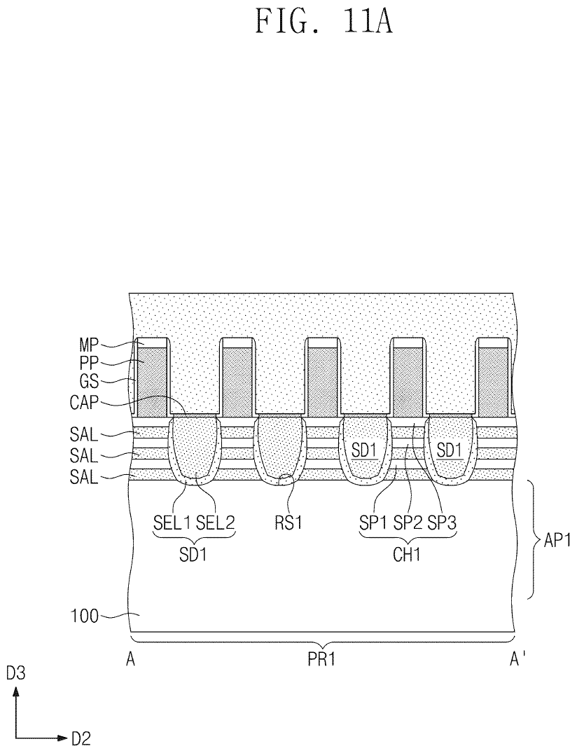

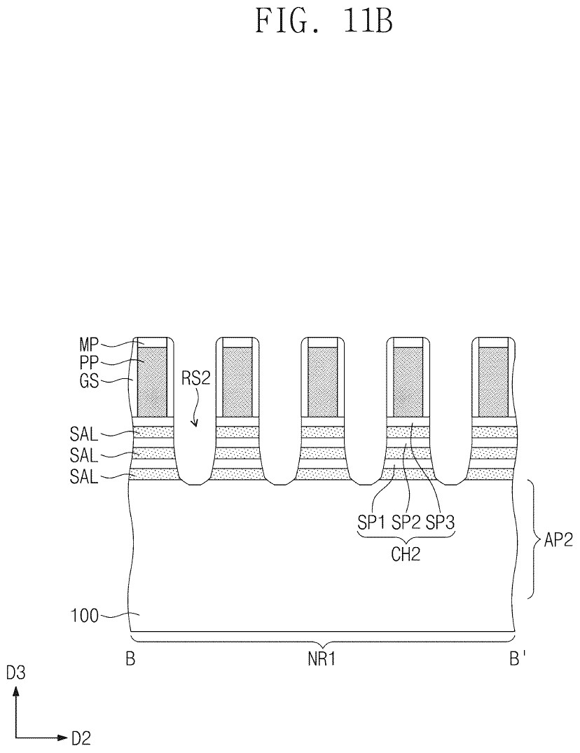

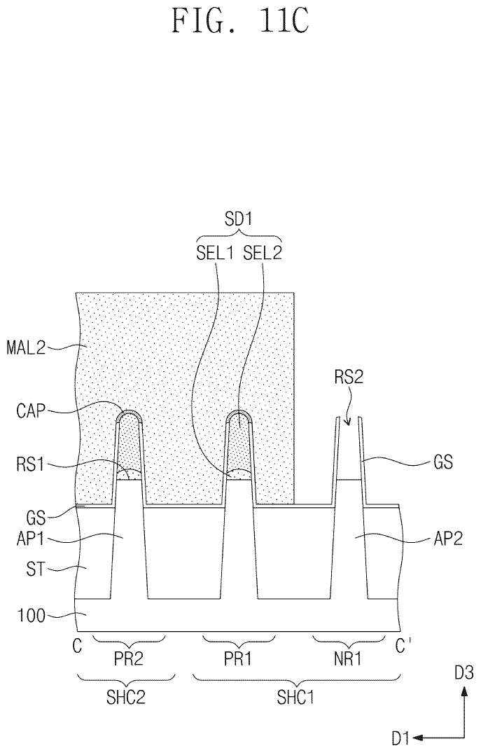

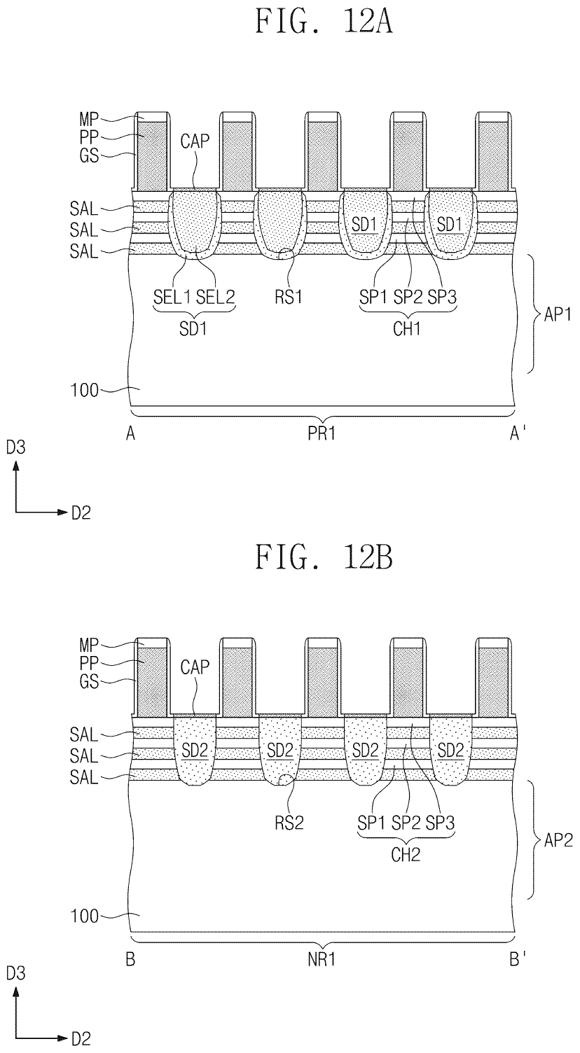

Referring to FIGS. 11A to 11C, a second mask layer MAL2 may be formed on the first and second PMOSFET regions PR1 and PR2. The second mask layer MAL2 may expose the first and second NMOSFET regions NR1 and NR2.

The second mask layer MAL2 may be used as an etching mask to etch the stack pattern STP between the sacrificial patterns PP on the second active pattern AP2, thereby forming a second recess RS2. The formation of the second recess RS2 may include using the hard mask pattern MP and the gate spacer GS as an etching mask to etch the stack pattern STP on the second active pattern AP2. The second recess RS2 may be formed between a pair of sacrificial patterns PP.

While the second recess RS2 is formed, an upper portion of the gate spacer GS on the first and second NMOSFET regions NR1 and NR2 may also be removed and recessed. The formation of the second recess RS2 may be substantially the same as the formation of the first recess RS1. The partial recessing of the gate spacer GS on the first and second NMOSFET regions NR1 and NR2 may be substantially the same as that discussed with reference to FIGS. 16 to 18.

The active layers ACL on the second active pattern AP2 may be formed into first, second, and third semiconductor patterns SP1, SP2, and SP3 that are sequentially stacked between neighboring second recesses RS2. A second channel pattern CH2 may be constituted by the first, second, and third semiconductor patterns SP1, SP2, and SP3 between neighboring second recesses RS2.

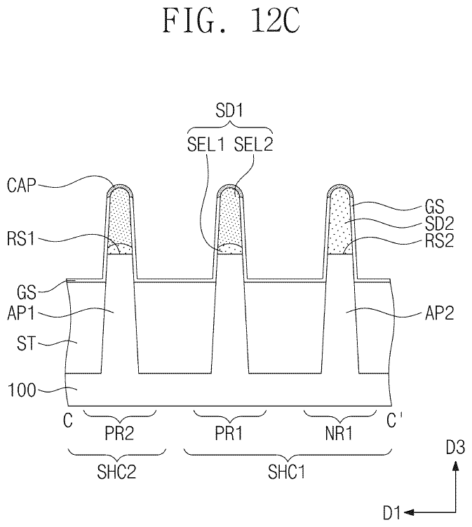

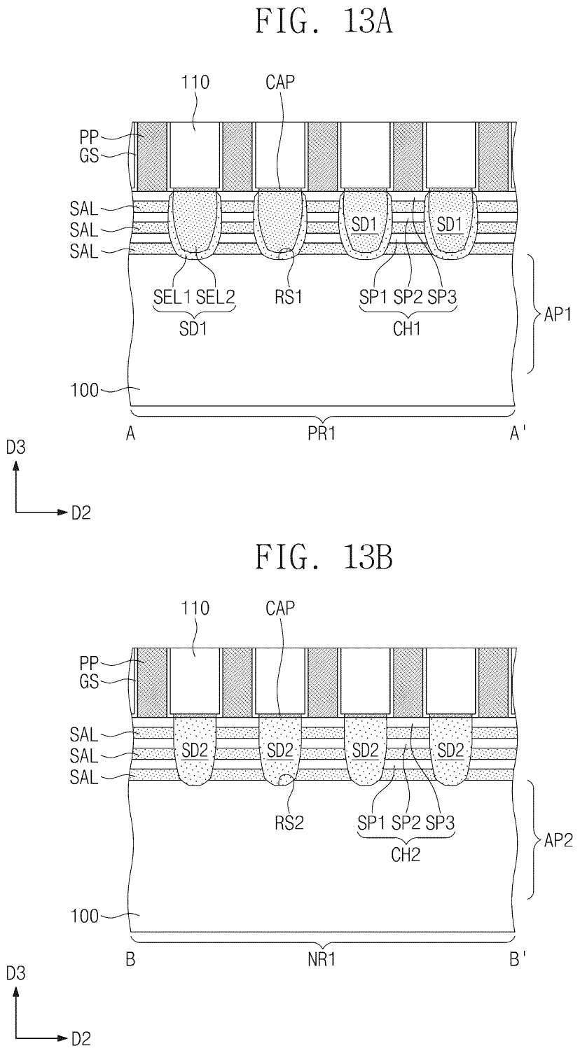

Referring to FIGS. 12A to 12C, the second mask layer MAL2 may be selectively removed. Second source/drain patterns SD2 may be formed in the second recesses RS2, respectively. For example, a third selective epitaxial growth (SEG) process may be performed in which an inner wall of the second recess RS2 is used as a seed to form the second source/drain pattern SD2. For example, the second source/drain pattern SD2 may include the same semiconductor element (e.g., Si) as that of the substrate 100.

The second source/drain pattern SD2 may be doped to have a second conductivity type (e.g., n-type). As the first and second NMOSFET regions NR1 and NR2 are covered with the gate spacer GS during the third SEG process, no semiconductor layer may be separately grown. Inner spacers IP may be formed between the second source/drain pattern SD2 and the sacrificial layers SAL, respectively.

The gate spacer GS may cause the second source/drain pattern SD2 to grow to have a fin shape. As discussed with reference to FIG. 18, a width in the first direction D1 of the second source/drain pattern SD2 may decrease with increasing distance in the vertical direction D3 from a bottom surface of the second recess RS2.

A silicon cap CAP may be formed on the second source/drain pattern SD2. The formation of the silicon cap CAP on the second source/drain pattern SD2 may be substantially the same as the formation of the silicon cap CAP on the first source/drain pattern SD1.

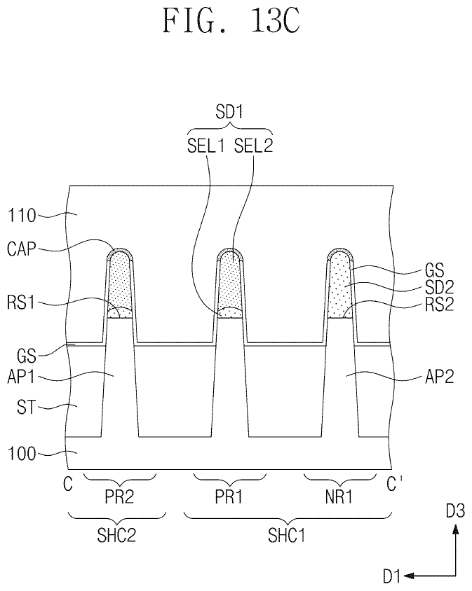

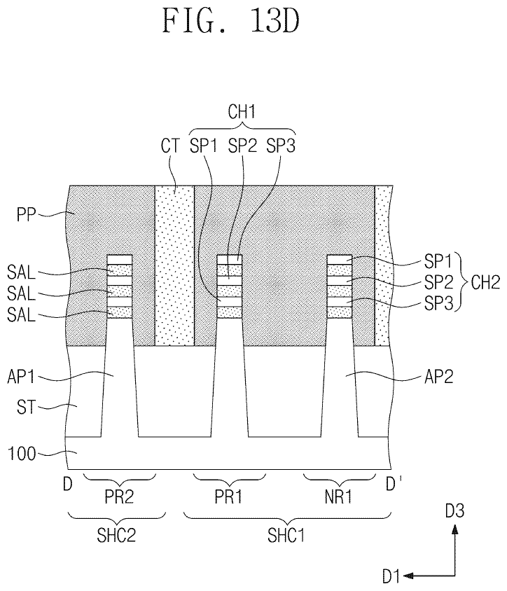

Referring to FIGS. 13A to 13D, a first interlayer dielectric layer 110 may be formed to cover the hard mask patterns MP and the gate spacers GS. For example, the first interlayer dielectric layer 110 may include a silicon oxide layer.

The first interlayer dielectric layer 110 may be planarized until the top surfaces of the sacrificial patterns PP are exposed. An etch-back or chemical mechanical polishing (CMP) process may be used to planarize the first interlayer dielectric layer 110. The hard mask patterns MP may be entirely removed during the planarization process. Thus, the first interlayer dielectric layer 110 may have a top surface coplanar with those of the sacrificial patterns PP and those of the gate spacers GS.

A photolithography process may be used to selectively open one region of the sacrificial pattern PP. For example, a portion of the sacrificial pattern PP on a boundary of the first single height cell SHC1 may be selectively opened. The opened portion of the sacrificial pattern PP may be selectively etched and removed. A space where the sacrificial pattern PP is removed may be filled with a dielectric material to form a gate cutting pattern CT.

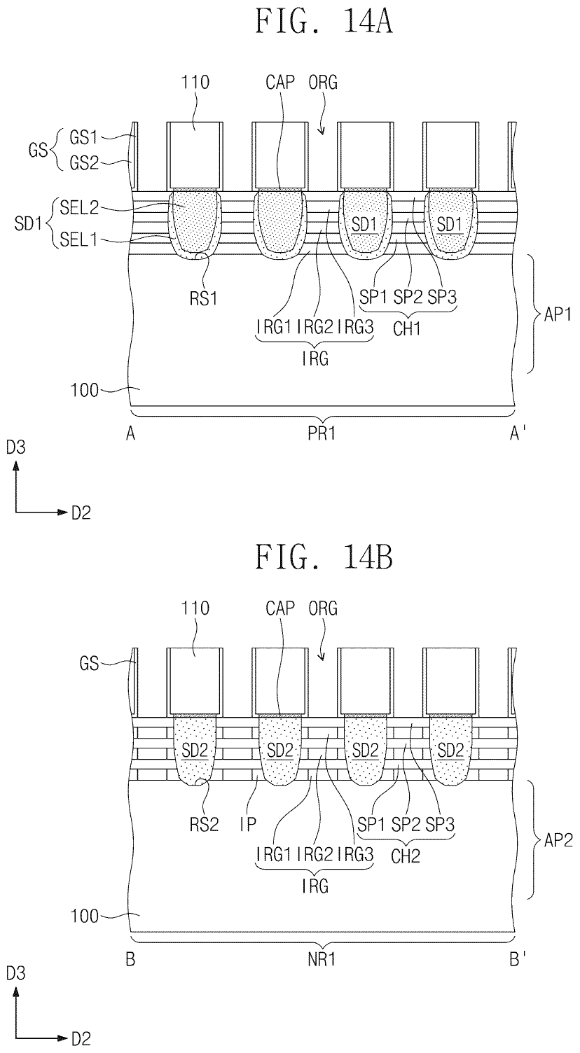

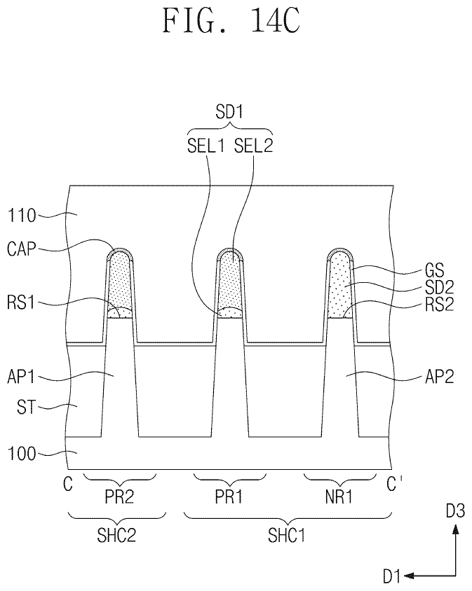

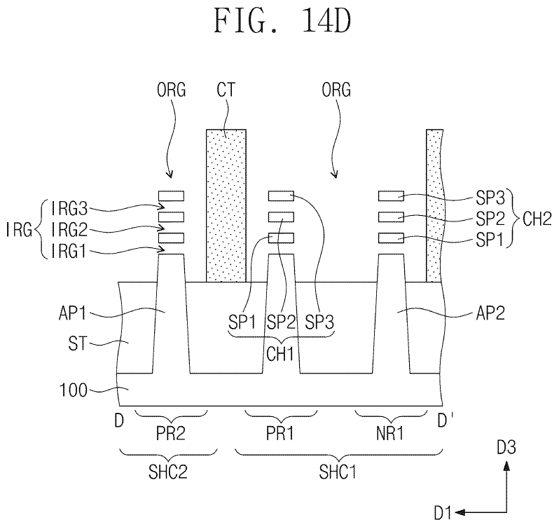

Referring to FIGS. 14A to 14D, the exposed sacrificial patterns PP may be selectively removed. The removal of the sacrificial patterns PP may form an outer region ORG that exposes the first and second channel patterns CH1 and CH2 (see FIG. 14D). The removal of the sacrificial patterns PP may include performing a wet etching process using an etchant that selectively etches polysilicon.

The sacrificial layers SAL exposed through the outer region ORG may be selectively removed to form inner regions IRG (see FIG. 14D). For example, an etching process that selectively etches the sacrificial layers SAL may be performed such that only the sacrificial layers SAL may be removed while leaving the first, second, and third semiconductor patterns SP1, SP2, and SP3. The etching process may use a high etch rate for silicon-germanium whose germanium concentration is relatively high. For example, the etching process may have a high etch rate for silicon-germanium whose germanium concentration is greater than about 10 at %.

During the etching process, the sacrificial layers SAL may be removed from the first and second PMOSFET regions PR1 and PR2 and from the first and second NMOSFET regions NR1 and NR2. The etching process may be a wet etching process. The etching material used for the etching process may promptly etch the sacrificial layer SAL whose germanium concentrate is relatively high. During the etching process, the first source/drain pattern SD1 on the first and second PMOSFET regions PR1 and PR2 may be protected by the first semiconductor layer SEL1 whose germanium concentration is relatively low.

As the sacrificial layers SAL are selectively removed, the first, second, and third semiconductor patterns SP1, SP2, and SP3 may remain on each of the first and second active patterns AP1 and AP2. The removal of the sacrificial layers SAL may form first, second, and third inner regions IRG1, IRG3, and IRG3. For example, the first inner region IRG1 may be formed between the active pattern AP1 or AP2 and the first semiconductor pattern SP1, the second inner region IRG2 may be formed between the first semiconductor pattern SP1 and the second semiconductor pattern SP2, and the third inner region IRG3 may be formed between the second semiconductor pattern SP2 and the third semiconductor pattern SP3.

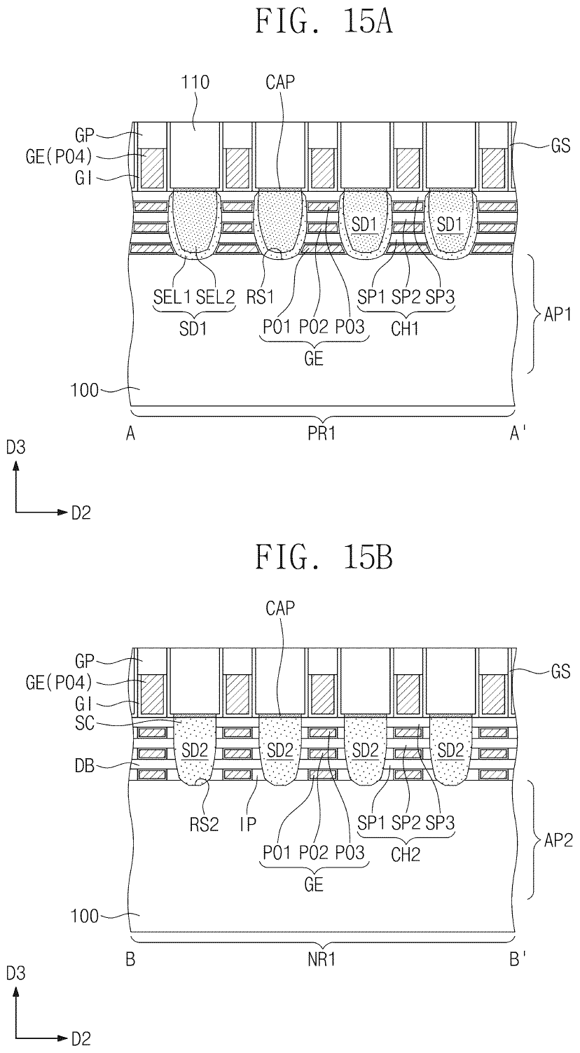

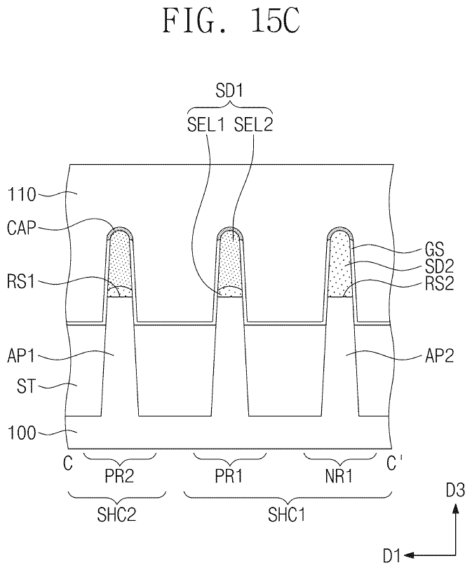

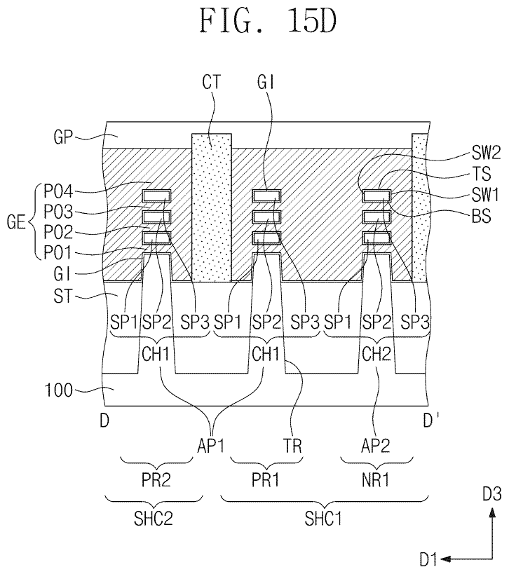

Referring to FIGS. 15A to 15D, a gate dielectric layer GI may be conformally formed on the first, second, and third semiconductor patterns SP1, SP2, and SP3 that are exposed. A gate electrode GE may be formed on the gate dielectric layer GI. The gate electrode GE may include first, second, and third parts PO1, PO2, and PO3 that are formed in the first, second, and third inner regions IRG1, IRG2, and IRG3, respectively, and may also include a fourth part PO4 formed in the outer region ORG.

The gate electrode GE may be recessed to have a reduced height. While the gate electrode GE is recessed, an upper portion of the gate cutting pattern CT may also be slightly recessed. A gate capping pattern GP may be formed on the recessed gate electrode GE.

Referring to FIGS. 4 and 5A to 5D, a second interlayer dielectric layer 120 may be formed on the first interlayer dielectric layer 110. The second interlayer dielectric layer 120 may include a silicon oxide layer. Active contacts AC may be formed to penetrate the second and first interlayer dielectric layers 120 and 110 to come into electrical connection with corresponding ones of the first and second source/drain patterns SD1 and SD2, respectively. A gate contact GC may be formed to penetrate the second interlayer dielectric layer 120 and the gate capping pattern GP to come into electrical connection with the gate electrode GE.

A pair of separation structures DB may be formed on opposite sides of each of the first and second single height cells SHC1 and SHC2. The separation structure DB may extend from the second interlayer dielectric layer 120 through the gate electrode GE into the active pattern AP1 or AP2. The separation structure DB may include a dielectric material, such as a silicon oxide layer or a silicon nitride layer.

A third interlayer dielectric layer 130 may be formed on the active contacts AC and the gate contacts GC. A first metal layer M1 may be formed in the third interlayer dielectric layer 130. A fourth interlayer dielectric layer 140 may be formed on the third interlayer dielectric layer 130. A second metal layer M2 may be formed in the fourth interlayer dielectric layer 140.

According to an example fabrication method of the inventive concepts, the gate spacer GS may include a material having an etch selectivity with respect to silicon (Si). Thus, while the first and second recesses RS1 and RS2 are formed, the gate spacer GS may remain without being removed. Accordingly, a height of the gate spacer GS may be adjusted.

In addition, only an upper portion of the gate spacer GS may be removed, and a side part of the gate spacer GS may remain to cover a sidewall of the stack pattern STP. Thus, the side part of the gate spacer GS may cause that the first and second source/drain patterns SD1 and SD2 are formed to have their fin shape. Thus, neighboring first and second source/drain patterns SD1 and SD2 may be alleviated or prevented from being in contact with each other due to a reduction in width of the neighboring first and second source/drain patterns SD1 and SD2, and accordingly a device may have an advantage of reliability increase and high integration.

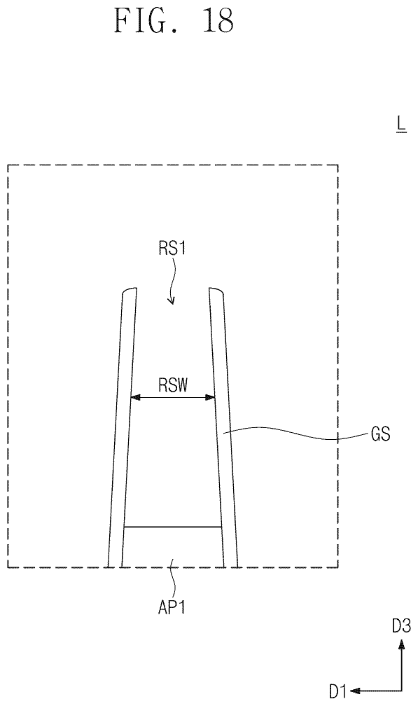

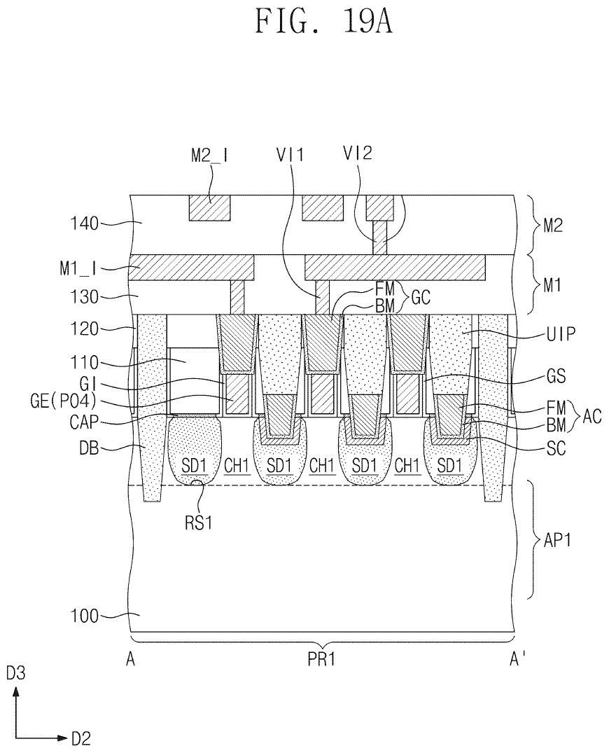

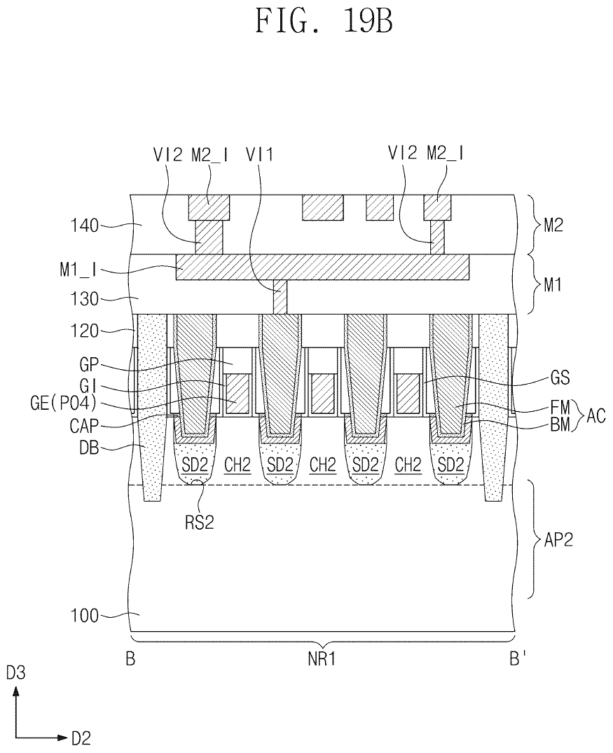

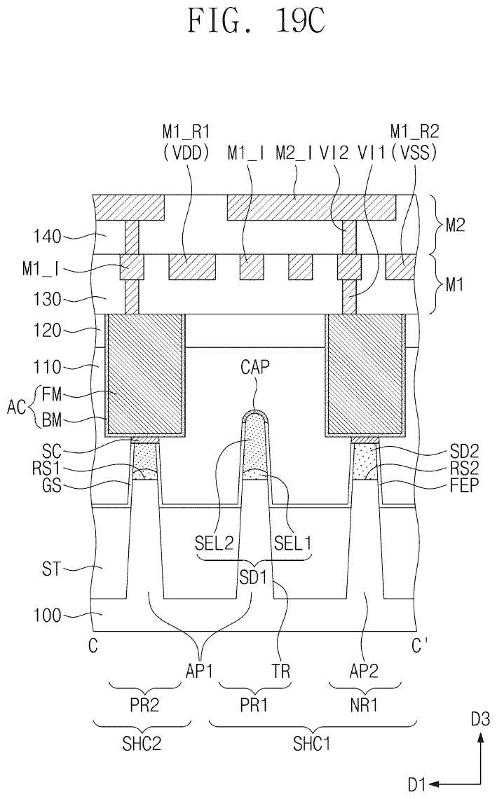

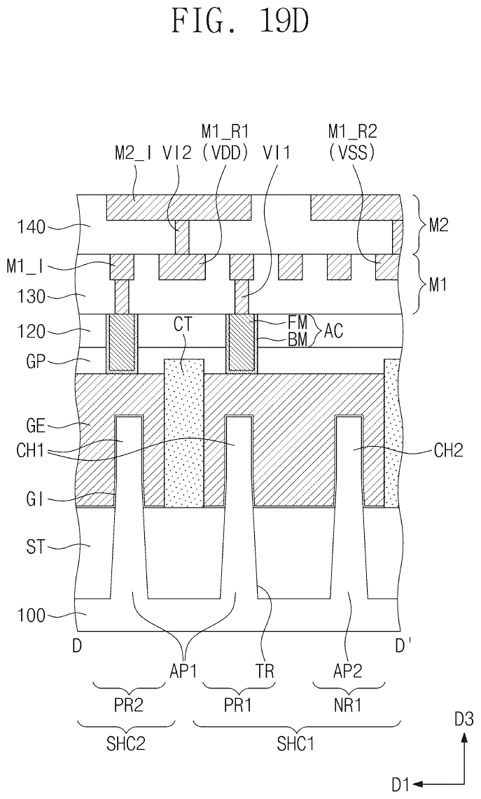

FIGS. 19A, 19B, 19C, and 19D illustrate cross-sectional views taken along lines A-A′, B-B′, C-C′, and D-D′ of FIG. 4, respectively, showing a semiconductor device according to an example embodiment of the inventive concepts. In the following description, a detailed description of technical features repetitive to those discussed above with reference to FIGS. 4 and 5A to 5D will be omitted, and a difference thereof will be discussed in detail.

Referring to FIGS. 4 and 19A to 19D, the device isolation layer ST may define a first active pattern AP1 and a second active pattern AP2 on an upper portion of the substrate 100. The first active pattern AP1 may be defined on each of the first PMOSFET region PR1 and the second PMOSFET region PR2, and the second active pattern AP2 may be defined on each of the first NMOSFET region NR1 and the second NMOSFET region NR2.

The device isolation layers ST may cover a lower sidewall of each of the first and second active patterns AP1 and AP2. An upper portion of each of the first and second active patterns AP1 and AP2 may protrude upwards from the device isolation layer ST (see FIG. 19D).

The first active pattern AP1 may include first source/drain patterns SD1 on an upper portion thereof and a first channel pattern CH1 between the first source/drain patterns SD1. The second active pattern AP2 may include second source/drain patterns SD2 on an upper portion thereof and a second channel pattern CH2 between the second source/drain patterns SD2.

Referring to FIG. 19D, each of the first and second channel patterns CH1 and CH2 may not include any of the first, second, and third semiconductor patterns SP1, SP2, and SP3 discussed above with reference to FIGS. 5A to 5D. Each of the first and second channel patterns CH1 and CH2 may have a semiconductor pillar shape that protrudes upwards from the device isolation layer ST.

The gate electrode GE may be provided on a top surface and opposite sidewalls of each of the first and second channel patterns CH1 and CH2. In this sense, a transistor according to some example embodiments may be a three-dimensional field effect transistor (e.g., FinFET) in which the gate electrode GE three-dimensionally surrounds the first and second channel patterns CH1 and CH2.

A first interlayer dielectric layer 110 and a second interlayer dielectric layer 120 may be provided on a front surface of the substrate 100. Active contacts AC may be provided to penetrate the first and second interlayer dielectric layers 110 and 120 to come into connection with the first and second source/drain patterns SD1 and SD2. A gate contact GC may be provided to penetrate the second interlayer dielectric layer 120 and the gate capping pattern GP to come into connection with the gate electrode GE. A detailed description of the active contacts AC and the gate contacts GC may be substantially the same as that discussed above with reference to FIGS. 4 and 5A to 5D.

A third interlayer dielectric layer 130 may be provided on the second interlayer dielectric layer 120. A fourth interlayer dielectric layer 140 may be provided on the third interlayer dielectric layer 130. A first metal layer M1 may be provided in the third interlayer dielectric layer 130. A second metal layer M2 may be provided in the fourth interlayer dielectric layer 140. A detailed description of the first metal layer M1 and the second metal layer M2 may be substantially the same as that discussed above with reference to FIGS. 4 and 5A to 5D.

In a semiconductor device according to the inventive concepts, a height of a gate spacer may be adjusted to reduce a maximum width of a source/drain pattern. In this case, the maximum width of the source/drain pattern may be the same as that of a semiconductor pattern. The source/drain pattern may have a width that decreases in a vertical direction. Thus, it may thus be possible to alleviate or prevent a short circuit caused by contact between neighboring source/drain patterns. Thus, the inventive concepts may achieve an improvement in reliability and electrical properties of devices.

Although some example embodiments of inventive concepts have been discussed with reference to accompanying figures, it will be understood that various changes in form and details may be made therein without departing from the spirit and scope of claims. The above disclosed example embodiments should thus be considered illustrative and not restrictive.

What is claimed is:

1. A semiconductor device, comprising:
an active pattern on a substrate;
a source/drain pattern on the active pattern;
a channel pattern on the active pattern and connected to the source/drain pattern, the channel pattern including a first semiconductor pattern; and
a gate electrode running across the channel pattern and extending in a first direction,
wherein a first width is a maximum width in the first direction of the source/drain pattern,
wherein a second width is a maximum width in the first direction of the first semiconductor pattern,
wherein a ratio of the second width to the first width is in a range of about 0.9 to about 1.1.

2. The semiconductor device of claim 1, wherein
the gate electrode includes a first gate electrode and a second gate electrode that are adjacent to each other in a second direction orthogonal to the first direction,
the semiconductor device further comprises a gate spacer between the first gate electrode and the second gate electrode, and
the gate spacer includes,
a first part covering a sidewall of the first gate electrode,
a second part covering a sidewall of the second gate electrode, and
a third part extending along the second direction from the first part to the second part.

3. The semiconductor device of claim 2, wherein
the source/drain pattern has an outer sidewall extending in the second direction, and
the third part covers the outer sidewall of the source/drain pattern.

4. The semiconductor device of claim 2, wherein the gate spacer includes at least one of SiOCN, AlO, or SiN.

5. The semiconductor device of claim 2, wherein
the source/drain pattern has a first outer sidewall and a second outer sidewall that are opposite to each other in the first direction, and
each of the first outer sidewall and the second outer sidewall is in direct contact with the gate spacer.

6. The semiconductor device of claim 2, further comprising:
a first interlayer dielectric layer on the gate spacer,
wherein the source/drain pattern is spaced apart from the first interlayer dielectric layer across the gate spacer.

7. The semiconductor device of claim 1, wherein
the source/drain pattern includes a first semiconductor layer and a second semiconductor layer on the first semiconductor layer,
a third width is a maximum width in the first direction of the second semiconductor layer, and
the third width is same as the second width.

8. The semiconductor device of claim 7, wherein a germanium concentration of the second semiconductor layer is greater than a germanium concentration of the first semiconductor layer.

9. The semiconductor device of claim 1, wherein
the channel pattern includes a plurality of semiconductor patterns that are stacked and spaced apart from each other, and
the first semiconductor pattern is an uppermost one of the plurality of semiconductor patterns.

10. The semiconductor device of claim 1, further comprising:
a silicon cap on the source/drain pattern.

11. A semiconductor device, comprising:
an active pattern on a substrate;
a source/drain pattern on the active pattern;
a gate electrode on the active pattern and extending in a first direction; and
a gate spacer on a sidewall of the source/drain pattern,
wherein the source/drain pattern has a first width in the first direction,
wherein the first width has a maximum value at a bottom surface of the source/drain pattern, and
wherein the first width decreases with increasing distance in a vertical direction from the bottom surface.

12. The semiconductor device of claim 11, wherein
the source/drain pattern includes,
a first part in the gate spacer, and
a second part on the first part, and
the semiconductor device further comprise a silicon cap on the second part.

13. The semiconductor device of claim 11, wherein the gate spacer includes at least one of SiOCN, AlO, or SiN.

14. The semiconductor device of claim 11, further comprising:
a channel pattern on the active pattern, the channel pattern including a first semiconductor pattern,
wherein a second width is a maximum width in the first direction of the source/drain pattern,
wherein a third width is a maximum width in the first direction of the first semiconductor pattern, and
wherein a ratio of the third width to the second width is in a range of about 0.9 to about 1.1.

15. The semiconductor device of claim 11, further comprising:
an active contact coupled to the source/drain pattern,
wherein a top level of the gate spacer is higher than a level of a bottom surface of the active contact.

16. A semiconductor device, comprising:
an active pattern on a substrate;
a source/drain pattern on the active pattern;
a channel pattern on the active pattern and connected to the source/drain pattern, the channel pattern including a plurality of semiconductor patterns that are stacked and spaced apart from each other;
a gate electrode across running the channel pattern and extending in a first direction;
a gate dielectric layer between the channel pattern and the gate electrode;
a gate spacer on a sidewall of the gate electrode;
a gate capping pattern on a top surface of the gate electrode;
a first interlayer dielectric layer on the gate capping pattern;
an active contact penetrating the first interlayer dielectric layer and coupled to the source/drain pattern;
a gate contact penetrating the first interlayer dielectric layer and coupled to the gate electrode;
a second interlayer dielectric layer on the first interlayer dielectric layer; and
a first metal layer in the second interlayer dielectric layer,
wherein the first metal layer includes a plurality of first wiring lines electrically connected to the active contact and the gate contact,
wherein the gate electrode includes a first gate electrode and a second gate electrode that are adjacent to each other in a second direction orthogonal to the first direction,
wherein the gate spacer includes,
a first part covering a first sidewall of the first gate electrode,
a second part covering a second sidewall of the second gate electrode, the first sidewall and the second sidewall being opposite to each other in the second direction, and
a third part extending along the second direction from the first part to the second part, and
wherein the source/drain pattern is in direct contact with the third part.

17. The semiconductor device of claim 16, wherein a width in the first direction of the source/drain pattern has a maximum value at a bottom surface of the source/drain pattern.

18. The semiconductor device of claim 16, wherein a top level of the gate spacer is higher than a level of a bottom surface of the active contact.

19. The semiconductor device of claim 16, wherein the source/drain pattern is spaced apart from the first interlayer dielectric layer across the third part.

20. The semiconductor device of claim 16, wherein a width in the first direction of the source/drain pattern decreases with increasing distance in a vertical direction from a bottom surface of the source/drain pattern.
